(19) United States
(12) Patent Application Publication
(10) Pub. No.: US 2016/0233379 A1
(43) Pub. Date: Aug. 11, 2016

(54) TERAHERTZ SOURCE CHIP, SOURCE DEVICE AND SOURCE ASSEMBLY, AND MANUFACTURING METHODS THEREOF

(71) Applicant: SUZHOU INSTITUTE OF NANO-TECH AND NANO-BIONICS (SINANO), CHINESE ACADEMY OF SCIENCES, Jiangsu (CN)

(72) Inventors: Hua Qin, Jiangsu (CN); Jiandong Sun, Jiangsu (CN); Yongdan Huang, Jiangsu (CN); Zhongxin Zheng, Jiangsu (CN); Dongmin Wu, Jiangsu (CN); Yong Cai, Jiangsu (CN); Baoshun Zhang, Jiangsu (CN)

(21) Appl. No.: 15/022,471

(22) PCT Filed: Sep. 18, 2014
(86) PCT No.: PCT/CN2014/086873

§ 371 Date: Mar. 16, 2016

(30) Foreign Application Priority Data
Sep. 18, 2013 (CN) 201310429725.8

(51) Int. Cl. H01L 33/10; H01L 33/06; H01L 33/32; H01L 33/58; H01L 33/34; H01L 33/28; H01L 33/26; H01L 33/54; H01L 33/00; H01L 33/30

(52) U.S. Cl. CPC H01L 33/105; H01L 33/0041; H01L 33/06; H01L 33/32; H01L 33/30; H01L 33/34; H01L 33/28; H01L 33/26; H01L 33/54; H01L 33/58; H01L 33/0095

(57) ABSTRACT

The present invention provides a terahertz source chip, a source device, a source assembly and manufacturing methods thereof. The source chip comprises: a two-dimensional electron gas mesa; an electrode formed on the two-dimensional electron gas mesa for exciting a plasma wave; a terahertz resonant cavity formed below the two-dimensional electron gas mesa, the terahertz resonant cavity having a total reflector on a bottom surface thereof; and a grating formed on the two-dimensional electron gas mesa for coupling a plasma wave pattern with a cavity mode of the terahertz resonant cavity to generate terahertz radiation. In the present invention, a plasmon polariton is formed by strongly coupling the cavity mode of the terahertz resonant cavity with the plasma wave mode in the two-dimensional electron gas below the grating, and the terahertz wave emission is realized by electrical excitation of the plasmon polariton. In this way, a problem of low frequency or low operating temperature caused by generating the terahertz emission based on high-frequency oscillation of a single electron or quantum transition of a single electron is avoided, and the emission frequency band and the operating temperature range are widened.

### TECHNICAL FIELD OF THE INVENTION

The present invention relates to the technology for generating terahertz radiation, and in more particular to a terahertz source chip, a source device and a source assembly, and manufacturing methods thereof.

### BACKGROUND OF THE INVENTION

Terahertz wave, as an electromagnetic wave having a band from 0.1 THz to 10 THz (1 THz=1000 GHz=10¹² Hz) and a wavelength from 30 μm to −3 mm, is between millimeter wave and infrared light, which is also known as sub-millimeter wave or far-infrared radiation. The radiation of the terahertz wave is also referred to as terahertz radiation. A device or an apparatus enabling to generate the terahertz radiation is referred to as a terahertz source or a terahertz emitter.

The existing technical solutions for generating the terahertz radiation may be mainly divided into the following three types.

The first type is an electronics technical solution where high-frequency electromagnetic wave radiation is generated by means of the accelerated motion of electrons and reciprocating motion of electrons in a real space or a momentum space. Such terahertz source devices include Gunn negative resistance oscillators, resonant tunneling diode oscillators, avalanche transit diode oscillators, oscillators based on transistors, and other electronic devices or circuits. The electronics technical solution further includes a technical solution where a microwave signal is subjected to several times of frequency multiplexing and power amplification to generate terahertz radiation.

The second type is a photonics technical solution where terahertz photons are generated by means of transition of electrons between quantized energy levels. The terahertz source based on this technology includes gas laser based on rotational energy level of gas molecules and quantum cascade laser based on artificial superlattice quantum energy levels.

The third type is a technical solution combining the photonics technology with the electronics technology. The third type mainly has a broadband terahertz source based on femtosecond ultrashort optical pulses, and the pump-probe technology and the nonlinear optical rectification and difference frequency technology thereof.

Additionally, there is also a technical solution where the terahertz radiation is generated by a terahertz emission source based on a plasma wave (also referred to as plasmon). This technical solution is not only different from the electronics solution based only on the motion of charges or the photonics solution based only on the transition of charges between energy levels, but also different form the femtosecond ultrashort pulse excitation technical solution.

The technical solution where the terahertz emission source is based on a plasma wave was earliest proposed in 1980 by D. C. Tsui, E. Gornik, R. A. Logan et al who found the terahertz emission from a plasma wave in a two-dimensional electron gas. In 1993, Dyakonov and Shur proposed a device structure and a shallow water wave theoretical model capable of effectively converting a DC current into the plasma wave excitation. However, the generation of the terahertz emission by this method always has problems of low emission efficiency, low power, and demand of low temperature. In U.S. Pat. No. 7,619,263 B2, Shur et al proposed that the detection, emission and manipulation of radio frequency signal and terahertz wave are realized by utilizing the plasma wave resonance in a high electron mobility transistor. The principle of this patent is based on the shallow water wave instability theory proposed by Dyakonov and Shur. Femtosecond laser beams are utilized to excite plasma waves in a two-dimensional electron gas, and the plasma waves and the terahertz wave are controlled by a source-drain voltage and a gate voltage applied to the device. In this inventive patent, the device includes a high electron mobility transistor having a single gate or a plurality of gates or a high electron mobility transistor having a grating gate. Additionally, U.S. Pat. No. 7,638,817 B2 by Shur et al further improves and supplements U.S. Pat. No. 7,619,263 B2, where a high electron mobility transistor with a sub-micron gate used as microwave and terahertz device was proposed, including detectors, sources and modulators. The proposed device structure can realize the detection, emission, and manipulation functions without requiring the same asymmetric boundary condition required by Dyakonov and Shur. U.S. Pat. No. 7,915,641 B2 by Otsuji et al proposed that the excitation of plasma waves is realized by incident laser beams. In this inventive patent, a double-grating modulated two-dimensional electron gas is irradiated by two beams of different frequency visible light or infrared light to realize the excitation of a plasma wave having an oscillation frequency of the differential frequency, and positive feedback is performed by utilizing a terahertz resonant cavity formed by the grating and a lower surface of a substrate to realize the amplification of the terahertz wave. The problem of low conversion efficiency from the plasma wave to the terahertz wave radiation is solved. The purpose of using double gratings in this inventive patent is to form a plasma wave with energy level splitting in the two-dimensional electron gas, so that the energy level splitting is equal to the frequency difference between the two beams of exciting light, thereby realizing the excitation of plasma wave from the visible light or infrared light. In this inventive patent, a method that combines the two-light beams excitation and the source-drain current of the two-dimensional electron gas was further proposed to improve the emission efficiency. In Chinese Patent Application CN101964500A, published in 2011, a method for realizing the electrical excitation of a plasma wave by the coupling between electron field emission in the terahertz wave and the cavity mode of a resonant cavity was proposed.

Plasma wave, which refers to the concentration fluctuation of charges of a same polarity in the background of charges of an opposite polarity, has characteristics of a wave and is a collective excitation mode of charges. The concentration fluctuation of charges in a specific mode, i.e., the plasma wave in a specific mode, becomes a plasmon. The plasma wave or the plasmon may be generated by exciting electron gas in solids. In a case of bulk material, it becomes a three-dimensional plasma wave or a three-dimensional plasmon. In the two-dimensional electron gas, it becomes a two-dimensional plasma wave or a two-dimensional plasmon.

A two-dimensional electron gas (2DEG) refers to a quasi-two-dimensional electron layer formed on a surface of a narrow bandgap semiconductor at a semiconductor heterojunction interface, for example, a two-dimensional electron gas on a GaAs surface at an AlGaAs/GaAs heterojunction interface, a two-dimensional electron gas on a GaN surface at an AlGaN/GaN heterojunction interface, and a two-dimensional electron gas on an Si surface at an Si/SiGe heterojunction interface. As electrons in the two-dimensional electron gas may be spatially separated from doped impurities effectively, the two-dimensional electron gas has a higher mobility than carriers in corresponding semiconductor material.

However, the mobility of the two-dimensional electron gas is finite. The plasma wave mode, due to the limited mobility of electrons, is low in quality factor and high in loss, and this is thus disadvantageous to improve the conversion efficiency from a drive current to the plasma wave excitation.

In the prior art where a terahertz emission source is realized based on plasma wave, solutions for problems such as low quality factor of the plasma wave have not been given explicitly.

Hence, a technical solution to improve the overall efficiency of plasma wave excitation is required.

### SUMMARY OF THE INVENTION

The present invention provides a terahertz source chip, a source device, a source assembly and manufacturing methods thereof, in order to eliminate at least one of problems caused by limitations or defects of the prior art.

According to one aspect of the present invention, a terahertz source chip is provided, including: an electron gas mesa; electrodes formed on the electron gas mesa; a terahertz resonant cavity formed below the electron gas mesa, the terahertz resonant cavity having a total reflector or a partial reflector on a bottom surface thereof; and a grating formed on the electron gas mesa.

The electron gas mesa is preferably a two-dimensional electron gas mesa. The electrode is used for exciting plasma waves. The grating is preferably a metal coupling grating.

The grating is used for coupling the plasma wave mode with the cavity mode of the terahertz resonant cavity to generate terahertz radiation.

The terahertz source chip also includes: a resonant cavity slab provided above the grating.

The resonant cavity slab may have a partial reflector or a total reflector formed on an upper surface or a lower surface thereof.

If a total reflector is arranged on a bottom surface of the terahertz resonant cavity, a partial reflector is formed on an upper surface or a lower surface of the resonant cavity slab; and if a partial reflector is arranged on a bottom surface of the terahertz resonant cavity, a total reflector is formed on an upper surface or a lower surface of the resonant cavity slab. The distance between the partial reflector and the total reflector preferably meets a standing wave condition and enables the standing wave to form an anti-node at the electron gas.

According to another aspect of the present invention, a terahertz source chip is provided, including: an electron gas mesa; an electrode formed on the electron gas mesa; a terahertz resonant cavity formed below the electron gas mesa, the terahertz resonant cavity having a total reflector or a partial reflector on a bottom surface thereof; and a grating formed on the electron gas mesa. The electrode includes: a source and a drain electrode both forming Ohmic contacts with the electron gas mesa, and a gate; wherein the grating is formed as the gate, or the gate is formed separately.

A voltage may be applied between the source and the drain to generate a drive current in the electron gas between the source and the drain, thus to excite a plasma wave in the electron gas. Preferably, the voltage applied between the source and the drain is tunable.

There is a potential difference between the gate and the electron gas, and the potential of the gate is lower than that of the electron gas to generate a tunneling current between the gate and the electron gas thus to excite plasma waves in the electron gas.

A negative voltage, a positive voltage or a zero-voltage, preferably a negative voltage, is applied to the gate. A DC voltage or an AC voltage is applied to the gate. The tunneling current is generated by the tunneling of electrons from the gate to the electron gas. A potential difference between the gate and the electron gas is tunable. The potential difference is less than the breakdown voltage of the electron gas material.

The electron gas mesa is preferably a two-dimensional electron gas mesa. The electron gas mesa may be made of electron gas material.

The electron gas material may be one or more of the following: GaN/AlGaN, InAlN/GaN, GaAs/AlGaAs, InGaAs/AlGaAs, Si/SiGe, InN, Si/SiO₂, graphene and MoS₂, diamond, single-layer, double-layer and triple-layer graphene, Si/SiO₂/Al metal-oxide-semiconductor, silicon nanowire, GaAs nanowire, InGaAs nanowire GaN nanowire, carbon nanotube, zinc oxide nanowire, doped silicon bulk material, doped GaAs bulk material, doped GaN bulk material, doped germanium bulk material, doped InGaAs bulk material, doped InP bulk material, doped SiC bulk material, doped diamond bulk material and doped zinc oxide bulk material. The electron gas material is preferably two-dimensional electron gas material, and may be one or more of the following: GaN/AlGaN, GaAs/AlGaAs, InGaAs/AlGaAs, Si/SiGe, InN, graphene and MoS₂.

The terahertz resonant cavity may be a slab-type resonant cavity or a curved resonant cavity.

The terahertz resonant cavity may be the substrate of the electron gas mesa.

The total reflector and the partial reflector may be one of the following structures: a spherical structure, an ellipsoidal structure, an aspheric structure and an asymmetric structure.

The grating is preferably a metal coupling grating.

The grating is used for coupling the plasma wave mode with the cavity mode of the terahertz resonant cavity to generate terahertz waves.

According to another aspect of the present invention, a terahertz source chip is provided, including: an electron gas mesa; an electrode formed on the electron gas mesa; a terahertz resonant cavity formed below the electron gas mesa, the terahertz resonant cavity having a total reflector or a partial reflector on a bottom surface thereof; and a grating formed on the electron gas mesa. The terahertz resonant cavity may be the substrate of the electron gas mesa The grating is used for coupling the plasma wave mode with the cavity mode of the terahertz resonant cavity to generate terahertz waves.

According to another aspect of the present invention, a terahertz source chip is provided, including: an electron gas mesa; an electrode formed on the electron gas mesa; a terahertz resonant cavity formed below the electron gas mesa, the terahertz resonant cavity having a total reflector or a partial reflector on a bottom surface thereof; and a grating formed on the electron gas mesa. The terahertz resonant cavity may be the substrate of the electron gas mesa.

The thickness of the terahertz resonant cavity is determined by the target terahertz emission frequency. The thickness D of the resonant cavity is given by:

$$D = \frac{2 k - 1}{n} \frac{c}{4 {f}_{0}} , k = 1 , 2 , 3 , … ,$$

where ƒ₀ is the target terahertz emission frequency, n is the refractive index of a medium within the resonant cavity at terahertz band, c is the vacuum velocity of light, and k is an integer.

The thickness of the terahertz resonant cavity is less than 1000 μm, preferably less than 600 μm, and more preferably less than 400 μm.

A spacing of the grating is less than 50 μm, preferably less than 10 μm.

The length of the grating is less than 50 μm, preferably 50 nm to 10 μm.

The period of the grating is less than 10 μm, preferably less than 4 μm.

The terahertz resonant cavity is a slab-type resonant cavity or a curved resonant cavity.

The material of the terahertz resonant cavity is one or more of sapphire, quartz crystal and high-resistance monocrystalline silicon.

The electron gas mesa is preferably a two-dimensional electron gas mesa.

The electron gas mesa is made of electron gas material.

The electron gas material may be one or more of the following: GaN/AlGaN, InAlN/GaN, GaAs/AlGaAs, InGaAs/AlGaAs, Si/SiGe, InN, Si/SiO2, graphene and MoS₂, diamond, single-layer, double-layer and triple-layer graphene, Si/SiO₂/Al metal-oxide-semiconductor, silicon nanowire, GaAs nanowire, InGaAs nanowire GaN nanowire, carbon nanotube, zinc oxide nanowire, doped silicon bulk material, doped GaAs bulk material, doped GaN bulk material, doped germanium bulk material, doped InGaAs bulk material, doped InP bulk material, doped SiC bulk material, doped diamond bulk material and doped zinc oxide bulk material.

The electron gas material is preferably two-dimensional electron gas material, and may be one or more of the following: GaN/AlGaN, GaAs/AlGaAs, InGaAs/AlGaAs, Si/SiGe, InN, graphene and MoS₂.

The electrode includes: a source and a drain electrode both forming Ohmic contacts with the electron gas mesa, and a gate; wherein the grating is formed as the gate, or the gate is formed separately.

A voltage may be applied between the source and the drain to generate a drive current in the electron gas, thus to excite a plasma wave in the electron gas. Preferably, the voltage applied between the source and the drain is tunable.

There is a potential difference between the gate and the electron gas, so as to generate a tunneling current between the gate and the electron gas, thus to excite plasma waves in the electron gas. Preferably, the potential difference between the gate and the electron gas mesa is tunable.

There is a potential difference between the gate and the electron gas, and the potential of the gate is lower than that of the electron gas.

The tunneling current is generated by tunneling of electrons from the gate to the electron gas.

The potential difference is less than a breakdown voltage of the electron gas material.

The electrode is used for exciting plasma waves.

The total reflector and the partial reflector are of one of the following structures: a spherical structure, an ellipsoidal structure, an aspheric structure and an asymmetric structure.

reflector is: a metal or alloy reflector formed of a metal or alloy coating, where the metal or alloy may be gold, aluminum and silver, or Ti/Au, Ni/Au, Cr/Au or NiCr/Au films; or a superconducting reflector made of superconducting thin film material, where the superconducting thin film may be NbN, Nb or YiBaCuO—; or a distributed Bragg reflector formed by alternately stacking two kinds of dielectric material with different dielectric constants, where the dielectric material may be inorganic dielectric material or organic polymer dielectric material, for example, high-resistance silicon, sapphire, quartz, glass, polyethylene, polytetrafluoroethylene and TPX (polymethylpentene).

The reflector is preferably a metal or alloy reflector formed of a metal or alloy coating.

The metal or alloy coating may be gold, aluminum and silver, or Ti/Au, Ni/Au, Cr/Au or NiCr/Au films. [0057] The grating is preferably a metal coupling grating.

The grating is used for coupling the plasma wave mode with the cavity mode of the terahertz resonant cavity to generate terahertz radiation.

According to another aspect of the present invention, a terahertz source chip is further provided, including: an electron gas mesa; an electrode formed on the electron gas mesa; a terahertz resonant cavity formed below the electron gas mesa, the terahertz resonant cavity having a partial reflector on a bottom surface thereof; a grating formed on the electron gas mesa; a resonant cavity slab provided above the grating; and a total reflector formed on an upper surface or a lower surface of the resonant cavity slab.

According to another aspect of the present invention, a terahertz source device is further provided, including the terahertz source chip of the aforementioned structure, the terahertz source chip being encapsulated on a chip holder or a printed circuit board.

According to another aspect of the present invention, a terahertz source assembly is further provided, including the terahertz source device, the terahertz source device being integrated into a waveguide.

According to another aspect of the present invention, a method for manufacturing the terahertz source chip is further provided, including steps of: forming an electron gas mesa on an electron gas substrate; forming electrodes and gratings for exciting a plasma wave on the electron gas mesa; and forming a terahertz resonant cavity based on the electron gas substrate, wherein forming the terahertz resonant cavity includes steps of: thinning and polishing the electron gas substrate from the back of the substrate to obtain a predetermined thickness of the resonant cavity and a predetermined mirror-level flatness; and forming a total reflector or a partial reflector on the back surface of the thinned and polished electron gas substrate.

The electron gas mesa is preferably a two-dimensional electron gas mesa.

The grating is preferably a metal coupling grating.

The method further includes a step of: integrating a resonant cavity slab above the grating in parallel, wherein a total reflector is arranged on a bottom surface of the terahertz resonant cavity, and a partial reflector is formed on an upper surface or a lower surface of the resonant cavity slab; or, a partial reflector is arranged on a bottom surface of the terahertz resonant cavity, and a total reflector is formed on an upper surface or a lower surface of the resonant cavity slab.

A distance between the partial reflector and the total reflector preferably meets a standing wave condition and enables the standing wave to form an anti-node at the electron gas.

According to another aspect of the present invention, a method for forming the terahertz source chip is further provided, including steps of: transferring electron gas material onto the upper surface of the terahertz resonant cavity, wherein the terahertz resonant cavity has a total reflector or a partial reflector on the lower surface thereof; forming an electron gas mesa on the upper surface of the terahertz resonant cavity; and

forming an electrode and a grating for exciting a plasma wave on the electron gas mesa.

The electron gas material is preferably two-dimensional electron gas material.

The electron gas mesa is preferably a two-dimensional electron gas mesa.

The grating is preferably a metal coupling grating.

The method further includes a step of: integrating a resonant cavity slab above the grating in parallel, wherein a total reflector is arranged on a bottom surface of the terahertz resonant cavity, and a partial reflector is formed on an upper surface or a lower surface of the resonant cavity slab; or, a partial reflector is arranged on a bottom surface of the terahertz resonant cavity, and a total reflector is formed on an upper surface or a lower surface of the resonant cavity slab.

The distance between the partial reflector and the total reflector preferably meets a standing wave condition and enables the standing wave to form an anti-node at the electron gas.

According to another aspect of the present invention, a method for manufacturing the terahertz source chip is further provided, including steps of: forming an electron gas mesa on an electron gas substrate; forming electrodes and gratings for exciting a plasma wave on the electron gas mesa; and forming a terahertz resonant cavity based on the electron gas substrate, wherein forming the terahertz resonant cavity includes steps of: thinning and polishing the electron gas substrate from the back of the substrate to obtain a predetermined thickness of the resonant cavity and a predetermined mirror-level flatness; forming a partial reflector on the back of the thinned and polished electron gas substrate; and integrating a resonant cavity slab above the metal coupling grating, wherein a total reflector is formed on an upper surface or a lower surface of the resonant cavity slab.

According to another aspect of the present invention, a method for manufacturing the terahertz source device is further provided, including steps of: encapsulating the manufactured terahertz source chip on a chip holder or a printed circuit board to form the terahertz source device.

According to another aspect of the present invention, a method for forming the terahertz source assembly is further provided, including steps of: integrating the terahertz source device with a terahertz waveguide to form the terahertz source assembly.

According to another aspect of the present invention, a method for exciting plasmons is further provided, and the excitation of plasmon is realized by injecting tunneling electrons into the electron gas.

The electron gas is preferably two-dimensional electron gas.

In the method for exciting plasmons, the tunneling electrons are injected by a potential difference applied between the electrode and an electron gas channel.

The potential difference is formed because the potential of the electrode is lower than that of the electron gas channel.

The potential difference is formed by applying a negative voltage, a positive voltage or a zero-voltage, preferably a negative voltage, to the electrode.

The potential difference is formed by applying a DC voltage or an AC voltage to the electrode.

The electrode is a gate.

According to another aspect of the present invention, a device for exciting plasmons is further provided, including: an electrode; an electron gas channel; and a barrier layer between the electrode and the electron gas channel. There is a potential difference between the electrode and the electron gas channel, and the potential of the electrode is lower than that of the electron gas channel.

The potential difference is less than a breakdown voltage of the barrier layer.

The barrier layer is semiconductor material, a vacuum layer or quantum well material.

The potential difference is formed by applying a negative voltage, a positive voltage or a zero-voltage to the electrode. Preferably, the potential difference is formed by applying a negative voltage to the electrode.

The potential difference is formed by applying a DC voltage or an AC voltage to the electrode.

The electrode is a gate.

According to another aspect of the present invention, a terahertz strong coupling device further provided, including a grating and a terahertz resonant cavity, the grating being located above the terahertz resonant cavity.

The grating is preferably a metal coupling grating.

The thickness of the terahertz resonant cavity is determined by a target terahertz emission frequency. The thickness D of the resonant cavity is given by:

$$D = \frac{2 k - 1}{n} \frac{c}{4 {f}_{0}} , k = 1 , 2 , 3 , … ,$$

where ƒ₀ is the target terahertz emission frequency, n is the refractive index of a medium within the resonant cavity at the terahertz band, c is the vacuum velocity of light, and k is an integer.

The thickness of the terahertz resonant cavity is less than 1000 μm, preferably less than 600 μm, and more preferably less than 400 μm.

A spacing of the grating is less than 50 μm, preferably less than 10 μm.

The length of the grating is less than 50 μm, preferably 50 nm to 10 μm.

The period of the grating is less than 10 μm, preferably less than 4 μm.

The terahertz resonant cavity is a slab-type resonant cavity or a curved resonant cavity.

The material of the terahertz resonant cavity is one or more of sapphire, quartz crystal and high-resistance monocrystalline silicon.

The terahertz resonant cavity has a total reflector or a partial reflector on a bottom surface thereof.

The terahertz strong coupling device further includes: a resonant cavity slab provided above the grating, the resonant cavity slab and the terahertz resonant cavity being respectively on both sides of the grating. A total reflector is arranged on a bottom surface of the terahertz resonant cavity, and a partial reflector is formed on an upper surface or a lower surface of the resonant cavity slab; or, a partial is arranged on a bottom surface of the terahertz resonant cavity, and a total reflector is formed on an upper surface or a lower surface of the resonant cavity slab.

The distance between the partial reflector and the total reflector meets a standing wave condition and enables the standing wave to form an anti-node at the electron gas.

The total reflector and the partial reflector are of one of the following structures: a spherical structure, an ellipsoidal structure, an aspheric structure and an asymmetric structure.

The reflector is: a metal or alloy reflector formed from metal or alloy coating, where the metal or alloy may be gold, aluminum and silver, or Ti/Au, Ni/Au, Cr/Au or NiCr/Au films; or a superconducting reflector made of superconducting thin film material, where the superconducting thin film may be NbN, Nb or YiBaCuO—; or a distributed Bragg reflector formed by alternately stacking two kinds of dielectric material with different dielectric constants, where the dielectric material may be inorganic dielectric material or organic polymer dielectric material, for example, high-resistance silicon, sapphire, quartz, glass, polyethylene, polytetrafluoroethylene and TPX (polymethylpentene).

The reflector is preferably a metal or alloy reflector formed from a metal or alloy coating.

The metal or alloy coating may be gold, aluminum and silver, or Ti/Au, Ni/Au, Cr/Au or NiCr/Au films.

In the present invention, a plasmon polariton mode is formed by strongly coupling a terahertz wave mode within the terahertz resonant cavity with a plasma wave mode in the electron gas below the grating, and the terahertz wave can be generated by electrical excitation of the plasmon polariton. In this way, a problem of low frequency or low operating temperature caused by generating the terahertz radiation based on high-frequency oscillation of a single electron or quantum transition of a single electron is avoided, and the emission frequency band and the operation temperature range are widened.

### BRIEF DESCRIPTION OF THE DRAWINGS

FIG. 1 is a schematic diagram of the fundamental principle of the terahertz source according to implementations of the present invention.

FIG. 2 is a diagram showing the dispersion relation of a plasma wave and the dispersion relation of a cavity mode of a terahertz resonant cavity.

FIG. 3A is a top view of the terahertz source according to one implementation of

the present invention.

FIG. 3B is a sectional view and a current driving diagram of the terahertz source device in FIG. 3A.

FIG. 4 is a brief flowchart of manufacturing the terahertz source device according to one implementation of the present invention.

FIG. 5 is an example of technological processes of manufacturing a terahertz source assembly according to one implementation of the present invention.

FIG. 6 is a sectional view of a terahertz source device according to another implementation of the present invention.

FIG. 7 shows the plasma wave mode and a cavity mode of the terahertz resonant cavity generated by integrating a grating into a resonant cavity in the terahertz source.

FIG. 8 shows an emission spectrum controlled by a gate voltage and a source-drain voltage.

FIG. 9 is a brief flowchart of manufacturing the terahertz source device according to another implementation of the present invention.

FIG. 10 is an example of technological processes of manufacturing a terahertz source assembly according to another implementation of the present invention.

FIG. 11 shows a schematic diagram after the terahertz source chip is integrated with a waveguide.

FIG. 12 is a sectional view of a terahertz source device having a tunable resonant cavity length installation according to one implementation of the present invention.

FIG. 13 is a sectional view of a terahertz source device having a tunable resonant cavity length installation according to another implementation of the present invention.

FIG. 14 shows different emission spectra, due to different thickness of the terahertz resonant cavity (under same other structure parameters of the terahertz resonant cavity), of the terahertz source device according to one implementation of the present invention. Fig. A is the emission spectrum when the thickness of the terahertz cavity of the source device is 212 μm, and Fig. B is the emission spectrum when the thickness of the terahertz cavity of the source device is 609 μm. The smaller the length of the resonant cavity is, the stronger the coupling strength is, and the more obvious the plasmon polariton features is in the emission spectrum are.

FIG. 15 shows different terahertz emission spectra due to different thickness of the resonant cavity and different length, period and spacing of the grating. Fig. A shows that the thickness of the resonant cavity is 200 μm, and the period of the grating is 4 μm, the gate length is 2 μm, and the spacing thereof is 2 μm. Fig. B shows that the thickness of the resonant cavity is 70 μm, and the period of the grating is 6 μm, the gate length is 2 μm, and the spacing thereof is 4 μm. The larger the thickness of the resonant cavity is, the smaller the spacing of the emission line is; the smaller the length of the grating is, the higher the frequency of the plasmon is; and the smaller the spacing of the grating is, the stronger the coupling is, and the more obvious the plasmon polariton features is in the emission spectrum.

FIG. 16 is the emission spectrum of the source device under negative and positive gate voltages. The negative gate voltage has a strong modulation capability of the emission spectrum, but the positive gate voltage has a weak modulation capability of the emission spectrum.

FIG. 17 is a diagram showing the emission power of the device and gate current as a function of the gate voltage. When the gate voltage is negative, the conversion efficiency is high. When the voltage of the gate is positive, the conversion efficiency is low.

FIG. 18 is a comparison of the excitation efficiency by the source-drain current and by the gate current. The excitation efficiency enabled by the gate current is much higher than that by the source-drain current.

### DETAILED DESCRIPTION OF THE INVENTION

In implementations of the present invention, a terahertz source is realized by forming a plasmon polariton mode by strongly coupling a plasma wave mode with a cavity mode of a terahertz resonant cavity using a terahertz coupling grating. More specifically, a plasmon plaritron mode is formed by exciting a plasma wave in an electron gas by DC or AC voltage applied onto one or more electrodes of a terahertz source chip and strongly coupling the plasma wave mode with a terahertz wave mode in the resonant cavity using a grating, i.e., a new state having characteristics of both the plasma wave and the terahertz electromagnetic wave. Thus, the overall efficiency of conversion from the plasma wave to the terahertz radiation is improved. That is to say, in the present invention, by injecting DC or AC current into an electron gas to excite a plasma wave, the terahertz wave is generated since the grating and the terahertz resonant cavity strongly couple the plasma wave mode with the cavity mode of the terahertz resonant cavity to form the plasmon plariton mode. The concept of forming the plasmon plariton by strongly coupling the plasma wave mode with the cavity mode of the terahertz resonant cavity below the grating has not yet been proposed in the exciting terahertz source technologies.

First, in the method of the present invention, the plasmon is excited by injecting high-energy electrons into the electron gas, that is, tunneling electrons are injected from the electrode to the channel, and the plasmon is excited during the relaxation of the electrons from a high-energy state to a low-energy state in the electron gas. This process is basically independent of the tunneling transit-time. The method is applicable to a two-dimensional electron gas, and also applicable to a three-dimensional electron gas or an one-dimensional electron gas. The excitation of the plasmon is realized by disturbing the electron system in the channel, and is independent of the dimensionality of the electron gas. This method is essentially different from other methods where the plasmon is excited by a gate tunneling current. A method described in Document (V. Ryzhii, M. Shur, Analysis of tunneling-injection transit-time effects and self-excitation of terahertz plasma oscillations in high-electron-mobility transistors, Jpn. J. Appl. Phys. 41, 922-924 (2002)) depends on the interaction of the electrons with the plasmon during the transition of the electrons through a barrier layer of the gate, and hence, the excitation of the plasma wave can not be realized until the positive voltage of the gate meets a certain threshold condition. In our method, the excitation of the plasmon has no threshold voltage features. More particularly, by this method, the plasmon can be excited more effectively in the case that the gate voltage is negative.

In the present invention, the electrons are injected by a potential difference between the electrode and the electron gas. The potential difference means that the potential of the electrode is lower than that of the electron gas so that the electrons can be injected into the electron gas from the electrode. For example, the electron gas is grounded, and a negative voltage is applied to the electrode. A positive voltage, a negative voltage and a zero-voltage may be applied to the electrode, the potential difference is less than the breakdown voltage of the barrier layer, and the voltage on the electrode may be a DC or an AC voltages. The electrode may be the gate.

Plasma wave, which refers to the concentration fluctuation of a collection of charges of the same polarity in the background of charges of an opposite polarity, has characteristics of a wave and is a collective excitation mode of charges. The concentration fluctuation of charges in a specific mode, i.e., the plasma wave in a specific mode, becomes a plasmon. The plasma wave or the plasmon may be generated by exciting an electron gas in solids. In a case of bulk materials, it becomes a three-dimensional plasma wave or a three-dimensional plasmon. In the two-dimensional electron gas, it becomes a two-dimensional plasma wave or a two-dimensional plasmon.

The electron gas is an electronegative free electron system generated by ionizing, doping or polarizing solid material. As the electrons in this system cam move freely and fill a physical space allowed by the entire outside surroundings, and the motion of electrons is similar to that of gas molecules, such an electron system is referred to as an electron gas (when the concentration of the electron gas is higher and the interaction between electrons is strengthened, such an electron system is also referred to as an electron liquid). The electron gas may be an one-dimensional electron gas or a two-dimensional electron gas or a three-dimensional electron gas.

The one-dimensional electron gas (1DEG) is an electron system capable of moving freely in only one dimension. The one-dimensional electron gas material is silicon nanowire, GaAs nanowire, InGaAs nanowire, GaN nanowire, carbon nanotube and zinc oxide nanowire.

The two-dimensional electron gas (2DEG) is an electron system which is limited to move in one dimension while capable of moving freely in other two dimensions. The electron gas may be a quasi-two-dimensional electron layer formed on a surface of a narrow bandgap semiconductor at a semiconductor heterojunction interface, for example, a two-dimensional electron gas on a GaAs surface at an AlGaAs/GaAs heterojunction interface, a two-dimensional electron gas on a GaN surface at an AlGaN/GaN heterojunction interface, and a two-dimensional electron gas on an Si surface at an Si/SiGe heterojunction interface. The two-dimensional electron gas material is heterojunction material, for example, GaN/AlGaN, InAlN/GaN, GaAs/AlGaAs, InGaAs/AlGaAs, Si/SiGe and Si/SiO₂; or surface self-polarized material, for example, InN and diamond; or two-dimensional crystal material, for example, single-layer, double-layer and triple-layer graphene and MoS₂, or a metal-oxide-semiconductor capable of generating charge accumulation or charge inversion to form the two-dimensional electron gas, for example, an Si/SiO₂/Al metal-oxide-semiconductor.

The three-dimensional electron gas means that the electrons in the electron gas may move freely in all three dimensions. The three-dimensional electron gas material is a bulk material, for example, doped bulk semiconductor material, specifically doped silicon bulk material, doped GaAs bulk material, doped GaN bulk material, doped germanium bulk material, doped InGaAs bulk material, doped InP bulk material, doped SiC bulk material, doped diamond bulk material and doped zinc oxide bulk material.

The electron gas mesa is material which has a double-layer or multi-layer structure containing electron gas and a barrier layer and is located on the substrate. The one-dimensional electron gas mesa is nanowire material which is wrapped or covered with a barrier layer, or covered with double-barrier material, or covered with quantum well material, and located on the substrate; the two-dimensional electron gas mesa is two-dimensional electron gas material which is wrapped or covered with a barrier layer, or covered with double-barrier material, or covered with quantum well material, and located on the substrate; and the three-dimensional electron gas mesa is bulk material which is covered or wrapped with a barrier layer, or covered with semiconductor material of different types of free charges on one or more surfaces thereof, or covered with double-barrier material, or covered with quantum well material, and located on the substrate. The common characteristic of the three mesas is to provide an electron gas for generating a plasma wave and a barrier layer for injecting tunneling electrons.

The tunneling electrons are electrons transferred or transported by the tunneling effect. The electrons, due to their wave behaviors, are capable of passing through a barrier region having potential energy higher than the energy of the electrons themselves at a certain probability. This quantum mechanical effect is referred to as tunneling effect. The higher the energy of the electrons, the lower the barrier and the thinner the barrier layer are, the higher the tunneling probability is.

The barrier layer is electronic material having a high-energy state with respect to the charge state in adjacent electronic material, the charges in the adjacent electronic material need to obtain enough energy to enter this material region, or the charges within this region will spontaneously enter a low-energy state in the adjacent electronic material by the release (relaxation) of energy. Generally, the barrier layer is made of wide bandgap semiconductor material, for example, a gate insulating layer of a high-electron-mobility transistor (HEMT), a gate oxide layer of a silicon MOSFET, an interface of a heterojunction semiconductor and wide bandgap material layer in a semiconductor superlattice. There is also a barrier layer at an interface between the semiconductor material and the vacuum. The barrier layer further may also be quantum well material.

The electron channel is electron gas material within the electron gas mesa for containing free electrons and plasma waves, and also a passageway for the flowing of electrons.

The standing wave condition is a specific space size and a boundary condition that the electromagnetic field intensity distribution does not change over time. When the standing wave condition is met, positions of an anti-node and a node of the oscillation of the electromagnetic field at a certain frequency do not change over time, and the distribution of the field intensity at boundaries of this space range does not change over time too. Generally, the size of a certain dimension in this space is an integral multiple of half or a quarter of the wavelength of the electromagnetic wave in this space. Hence, the standing wave condition may be realized by limiting the size of space and the boundary condition, for example, the thickness of a Fabry-Perot resonant cavity determines the lowest frequency of the resonant cavity. A surface of the resonant cavity is the node when this surface is coated with metal, and the surface of the resonant cavity is the anti-node when this surface is not coated with metal.

The near-field effect is a phenomenon that the field intensity of the electromagnetic field is increased in a region adjacent to the metal or medium structure (generally within a sub-wavelength range).

The reflector may be a metal or alloy reflector mirror made of a metal coating, where the metal may be gold, aluminum and silver, or Ti/Au, Ni/Au, Cr/Au or NiCr/Au films; also may be a superconducting reflector made of superconducting thin film material, where the superconducting thin film may be NbN, Nb or YiBaCuO—; also may be a distributed Bragg reflector formed by alternately stacking two kinds of dielectric material with different dielectric constants, where the dielectric material may be inorganic dielectric material or organic polymer dielectric material, for example, high-resistance silicon, sapphire, quartz, glass, polyethylene, polytetrafluoroethylene and TPX (polymethylpentene).

The present invention will be explained below with respect to the following exemplary implementations.

Implementation 1

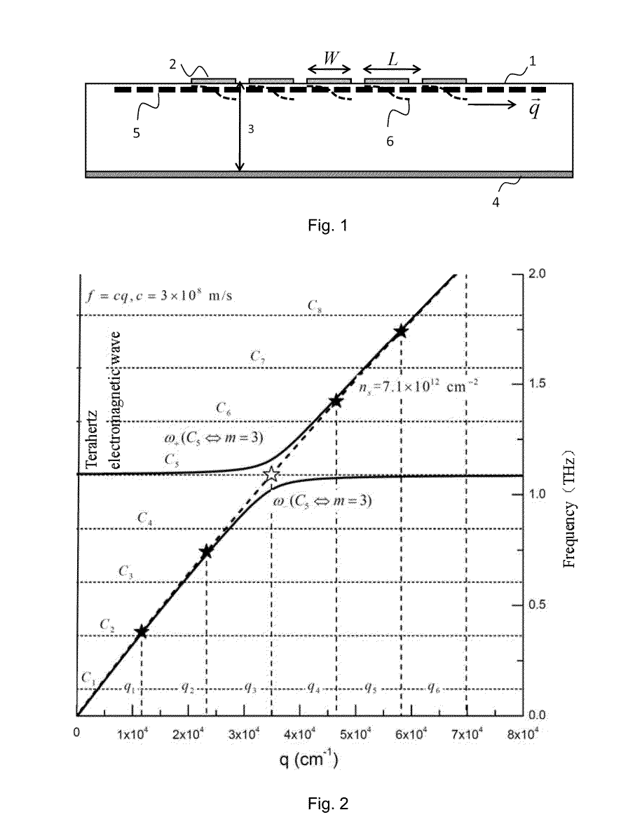

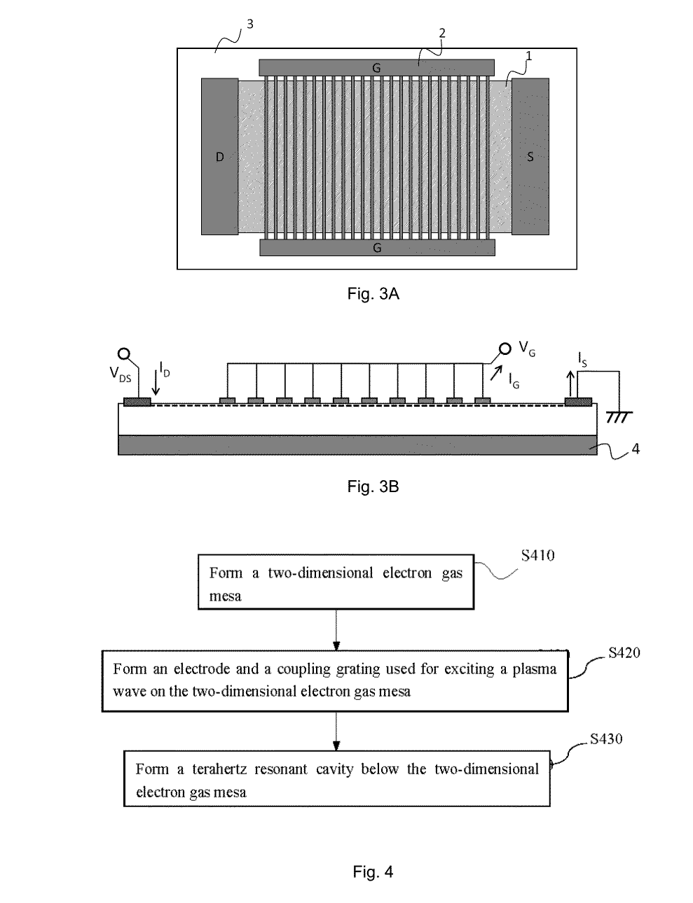

In this implementation, a terahertz source chip (also referred to as a first terahertz source chip in this implementation), a corresponding source device and assembly, and manufacturing methods thereof are provided. FIG. 1 is a schematic diagram of the principle of the terahertz source chip according to this implementation. FIG. 2 is a diagram showing the dispersion relation of a plasma wave and the dispersion relation of a cavity mode of a terahertz resonant cavity. FIG. 3A is a top structure view of the terahertz source according to this implementation, and FIG. 3B is a sectional view and a current driving diagram of the terahertz source chip of FIG. 3A.

As shown in FIG. 1, this terahertz source chip includes: a two-dimensional electron gas mesa 1; an electrode (not shown) formed on the two-dimensional electron gas mesa 1 for exciting a plasma wave 6; a terahertz resonant cavity 3 formed below the two-dimensional electron gas mesa 1 and having a total reflector 4 on a bottom surface thereof; and a metal coupling grating 2 formed on a surface of the two-dimensional electron gas mesa 1 for coupling a cavity mode of the terahertz resonant cavity with the two-dimensional electron gas and a plasma wave mode thereof to generate terahertz radiation.

The terahertz resonant cavity may have a high quality factor which is generally greater than or much greater than 10 and may be over 100, for example, 10000 or even higher. However, the quality factor of the plasma wave is low, approximately 10 to 100. Hence, the plasmon polariton formed by strongly coupling a terahertz wave mode with a plasma wave mode can improve the quality factor of the plasma wave and reduce the loss of the plasma wave. This is one of the core technologies for realizing high-efficiency terahertz source devices.

As shown in FIG. 1, in the present invention, the plasma wave in the high electron mobility two-dimensional electron gas 5 is used as an operating medium. The plasma wave 6 in a specific mode may be excited by driving the two-dimensional electron gas 5 in the two-dimensional electron gas mesa 1 by a current. Further, the high-efficiency coupling of the plasma wave with the terahertz electromagnetic wave may be realized by a metal grating (there is an strengthened terahertz electric field at the edges of the metal grating), and then, the strong coupling of the cavity mode of the terahertz wave with the plasma wave mode may be realized by a terahertz resonant cavity having a limited size to form the plasmon polariton, thus to obtain high-efficiency energy conversion from the plasma wave to the terahertz radiation. The mode volume of the resonant cavity should be as small as possible, so that stronger coupling efficiency between the terahertz wave and the plasma wave can be realized, thereby improving the efficiency of emitting the terahertz wave by the plasma wave. Assumed that the emission frequency is f₀, the thickness D of the resonant cavity may be:

$$D = \frac{2 k - 1}{n} \frac{c}{4 {f}_{0}} , k = 1 , 2 , 3 , … ,$$

where n is the reflective index of the medium within the resonant cavity at terahertz frequency, c is the vacuum velocity of light, and k is an integer. The smallest thickness of the resonant cavity is: Dₘᵢₙ=c/4nƒ₀. Whether the smallest size of the resonant cavity is used or not is mainly determined by the degree of difficulty of the manufacture process. This conlusion has been verified by the existing experimental results.

In this implementation, the electrode used for exciting the plasma wave may be a source and a drain both formed on the two-dimensional electron gas mesa 1 and forming Ohmic contact with the two-dimensional electron gas mesa 1; and also may be one of the source and the drain and a gate, where the gate may be a metal coupling grating or a separate gate separated from the metal coupling grating (the separate gate is not connected to the grating). FIG. 3A shows an example where a metal coupling grating serves as the gate (in this case, the coupling grating is equivalent to a plurality of gates) and the metal grating is located between the source and the drain.

For example, the plasma wave may be excited in the two-dimensional electron gas by one of the following two methods, that is, the electric energy is converted into the plasma wave energy in the two-dimensional electron gas.

(1) The drive current between the gate G and the two-dimensional electron gas, i.e., the current between the gate G and the source S and/or the current between the gate G and the drain D, may excite the plasma wave. The electric energy is converted into the plasma wave energy in the two-dimensional electron gas by the transportation of the electrons between the gate and the two-dimensional electron gas. An additional DC gate voltage and the terahertz electric field together modulate the tunneling current between the gate and the two-dimensional electron gas. As shown in FIG. 3B, a negative voltage V_{G} is applied to the gate G, and the concentration of the two-dimensional electron gas is tunable. Meanwhile, electrons may be tunneled to the two-dimensional electron gas from the gate to generate a tunneling current I_{G}. Of course, a positive voltage may be applied to the gate G. The voltage applied to the gate G is tunable.

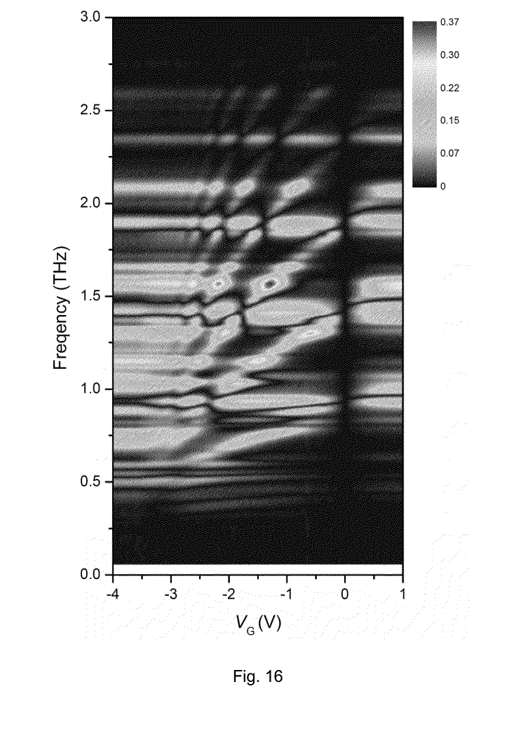

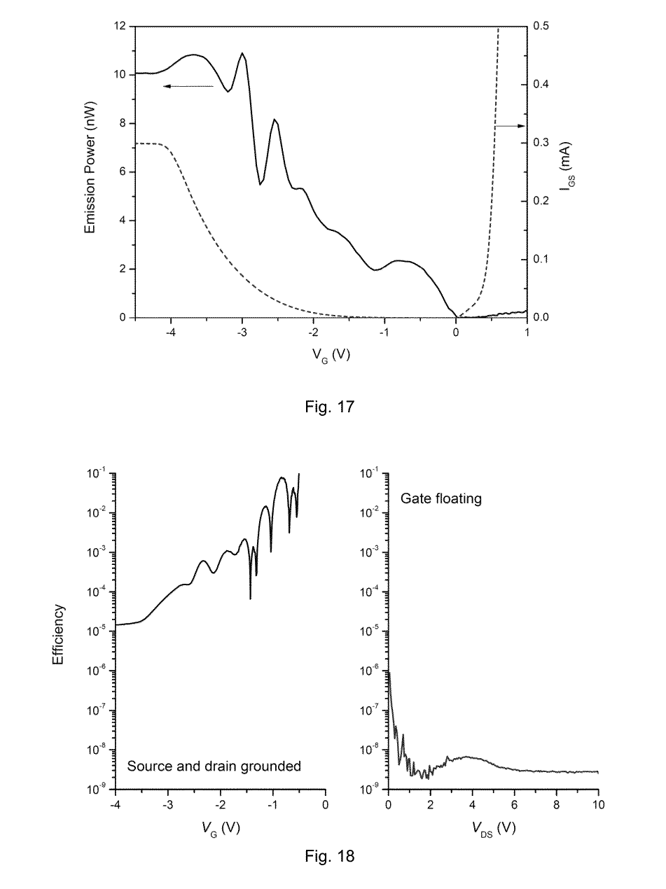

FIG. 16 and FIG. 17 show that the excitation efficiency of the terahertz wave is higher when the gate voltage is negative and the excitation efficiency of the terahertz wave is lower when the gate voltage is positive. FIG. 17 shows that, in the negative gate voltage region, the terahertz emission power and the gate current are gradually reduced when the gate voltage is gradually more negtive; and in the positive gate voltage region, both the emission power and the emission efficiency are lower than corresponding values under a negative gate voltage. In conclusion, the terahertz emission spectra will be better when a negative voltage is applied to the gate, and this has not yet been revealed in the prior art.

(2) A drive current between the source and the drain in the two-dimensional electron gas channel. The drift velocity of the electrons is increased by adding electric field between the source and the drain, in order to excite the plasma wave in the two-dimensional electron gas, thus to convert the electric energy into the plasma wave energy. As shown in FIG. 3B, a source S and a drain D at both ends of the two-dimensional electron gas mesa become Ohmic contacts with the two-dimensional electron gas mesa, and the drive currents I_{D} and I_{S} in a source-drain direction are generated in the two-dimensional electron gas mesa by applying a source-drain voltage V_{DS} between the source and drain electrodes.

FIG. 18 shows that the excitation efficiency by the gate current is much greater than that by the source-drain current.

In the present invention, the two-dimensional electron gas mesa may be made of two-dimensional electron gas material.

Generally, the two-dimensional electron gas material may be selected based on two major parameters of the two-dimensional electron gas. One of the parameters is high electron mobility. The higher the mobility is, the less the attenuation of the plasma wave is, and, the higher the emission efficiency is, the higher the operating temperature is. The terahertz emission at the room temperature is expected when the mobility at the room temperature reaches a level of 20000 cm²/Vs. The maximum operating temperature may be approximately 200 K when the mobility at the room temperature reaches a level of 2000 cm²/Vs. Hence, the mobility is an important parameter in the present invention, and two-dimensional material having a high electron mobility is preferably applied in the present invention. The second parameter is the density of the two-dimensional electron gas. The terahertz wave having a higher frequency may be emitted when the density is high. However, the emission frequency may be inscreased by reducing the length of the gate of the grating (the size in a source-drain direction is referred to as the length, and the size in a direction perpendicular to the source-drain direction is referred to as the width. The emission power is increased linearly when the width is increased) when the density is low (for example, lower than 10¹¹ cm⁻²). For instance, the length of the gate of the grating may be fabricated to be, for example, less than 1 μm. Here, 1 μm is merely given as an example, and the present invention is not limited thereto. Hence, the density is not a key parameter in the present invention. In a case that a gate separated from the grating is additionally provided, the length of the separate gate determines the plasma wave mode, and the period of the grating determines the optimum frequency of the coupling of the terahertz wave mode with the plasma wave mode. In a practical device, the resonance, i.e., the optimum and strongest coupling, may be achieved by tuning the gate voltage.

As an example, the two-dimensional electronic material may be, for example, a GaN/AlGaN heterojunction having a high electron mobility. The GaN/AlGaN heterojunction has a high electron concentration to widen the tunable range of the terahertz emission frequency and also has a capacity of a high current to improve the highest emission power. Alternatively, the two-dimensional electron gas material may also be other two-dimensional electron gas material having a high electron mobility at the room temperature, for example, GaAs/AlGaAs, Si/SiGe or InGaAs/AlGaAs heterojunctions. As a result, a solid terahertz source working at the room temperature may be realized. Additionally, the two-dimensional electron gas material may also be selected from graphene or MoS₂, InN and so on. The aforementioned listed two-dimensional electron gas materials are merely given as examples, and the present invention is not limited thereto.

The dispersion relation of the plasma wave in the two-dimensional electron gas is as follows:

$${f}_{p} = \frac{1}{2 π} \sqrt{\frac{{n}_{s} {e}^{2}}{2 {m}_{0} {m}^{*} {ɛ}_{0} ɛ} q}$$

where ƒ_{P} is the frequency (Hz) of the plasma wave, nₛ is the electron density (m⁻²) of the two-dimensional electron gas, ε₀=8.854×10⁻¹² F/m is a vacuum dielectric permitivity, m* is the effective mass of electrons in the two-dimensional electron gas, m₀=9.11×10⁻³¹ kg is the rest mass of electrons, e=1.602×10⁻¹⁹ Coulombs is the charge of electrons, q=2π/λ_{P} is the wave number of the plasma wave, λ_{P} is the wavelength of the plasma wave, and ε is an effective dielectric constant of the medium where the grating-coupled two-dimensional electron gas locate. A local plasma wave under the gate and a two-dimensional plasma wave expanded over the period scale of a plurality of gratings may be excited in the grating-coupled two-dimensional electron gas, and the plasma waves have specific modes. That is, the wave numbers of the plasma waves under the two conditions may be respectively expressed as:

$${q}_{m} = m \frac{π}{W} , m = 1 , 2 , 3 , … , \\ {q}_{m} = m \frac{2 π}{L} , m = 1 , 2 , 3 , … ,$$

where W is the length of the gate of the grating and L is the period of grating. In a case when one gate is provided separately, the mode is determined only by the length W of the gate. The period L of the grating determines whether the plasma wave mode can realize strong coupling with the cavity mode of the resonant cavity at a frequency determined by W, and the concentration of the electron gas may be tuned by the gate voltage to achieve the resonance between the plasma wave mode and the cavity mode of the resonant cavity.

When the frequency of the plasma wave is the same as that of the cavity mode of the resonant cavity, and the cavity mode of the resonant cavity has the strongest terahertz electric field where the grating-coupled two-dimensional electron gas locate(as shown in FIG. 7), the plasma wave mode and the cavity mode of the resonant cavity meet the resonance condition:

$${f}_{p} ( m ) = \frac{1}{2 π} \sqrt{\frac{{n}_{s} {e}^{2}}{2 {m}_{0} {m}^{*} {ɛ}_{0} ɛ} {q}_{m}} ⇔ {f}_{0} ( k ) = \frac{2 k - 1}{4} \frac{c}{nD} , m = 1 , 2 , 3 , … , k = 1 , 2 , 3 , …$$

As shown in FIG. 2, the terahertz electromagnetic wave in the free space is indicated by an approximately vertical straight line on the left side. Horizontal dotted lines parallel to a horizontal axis indicate the frequencies of the cavity mode C₁-C₈ of the terahertz resonant cavity ƒ₀(k), k=1,2,3, . . . 8, vertical dotted lines perpendicular to the horizontal axis correspond to the wave number of the local plasma wave modes under the gate determined by the coupling grating (qₘ=mπ/W, m=1,2,3, . . . 6, i.e., the frequency corresponding to the local plasma wave). The horizontal dotted lines and the vertical dotted lines are intersected to obtain resonant points of the cavity mode of the resonant cavity and the plasma wave. The resonance can be achieved only when the density of the two-dimensional electron gas meets the above resonance condition by tuning the gate voltage. In FIG. 2, an inclined bold broken curve corresponds to the dispersion relation of the plasma wave under a specific density of electron gas (nₛ32 7.1×10¹² cm⁻²) the terahertz wave mode supported by the coupling grating is indicated by five-pointed stars, and the plasma wave mode capable of being coupled with the terahertz wave mode is indicated by the hollow five-pointed star. For example, in FIG. 2, the plasma wave mode q₃ and the cavity mode C₅ of the terahertz resonant cavity can realize resonance. Hence, the terahertz source of the present invention may reach a light-emitting state by tuning the gate voltage, and the light-emitting efficiency may be tuned within a certain range.

The source chip of the present invention can not only achieve the aforementioned resonance condition, but also achieve the strong coupling between the cavity mode of the resonant cavity and the plasma wave mode. When the resonance condition is simply met, certain conversion from the plasma wave to the terahertz wave may be realized and the terahertz wave may be emitted, but the efficiency is low. The main reason is that the quality factor of the plasma wave is low:

$${Q}_{p} = {f}_{p} τ □ 10 , \\ τ = \frac{μ {m}_{0} {m}^{*}}{e} °$$

A plasmon polariton mode, i.e., being the terahertz cavity mode and the plasma wave mode simultaneously, may be formed, when the strong coupling condition between the cavity mode of the resonant cavity and the plasma wave mode as described in the present invention is achieved. The polariton sub-mode may be described by using a coupled oscillator model:

$${ω}_{\pm } = \frac{{ω}_{c} + {ω}_{p}}{2} - \frac{i}{2} ( {γ}_{p} + {γ}_{c} ) \pm \sqrt{{( \frac{{ω}_{c} - {ω}_{p}}{2} )}^{2} + {V}^{2} - {( \frac{{γ}_{p} - {γ}_{c}}{2} )}^{2} - \frac{i}{2} ( {ω}_{p} - {ω}_{c} ) ( {γ}_{p} - {γ}_{c} )}$$

where ω_{c}=2πƒ₀, ω_{P}=2πƒ_{P}, γ_{P}=2πτ⁻¹=2πƒ_{P}/Q_{P}, γ_{c}=2πƒ₀/Q_{c}, and Q_{c} are quality factors of the resonant cavity, and V is the coupling strength between the cavity mode of the resonant cavity and the plasma wave. A high-frequency polariton sub-mode and a low-frequency polariton sub-mode are formed when the cavity mode of the resonant cavity resonantwith the plasma wave. The sub-modes of polariton are indicated by solid curves in FIG. 2. At the resonance, the frequency difference between the two sub-modes is the Rabi oscillation frequency:

Ω_{R}=\sqrt{4V²−(γₚ−y_{c})²}

The greater the coupling strength is, the greater their frequency difference is, and the larger the tunable range of the frequency is.

Hence, according to implementations of the present invention, high-efficiency conversion from the plasma wave to the terahertz wave may be realized by using the plasmon plariton formed after coupling the cavity modes of the terahertz wave with the modes of the plasma wave.

In the implementations of the present invention, the resonant cavity, below the two-dimensional electron gas mesa formed from two-dimensional electron gas material, may be formed from insulating substrate material supporting the two-dimensional electron gas material, and may have a surface having a mirror-level flatness.

The substrate material of the terahertz resonant cavity is selected on the following basis: having absorption of the terahertz wave as small as possible, meanwhile meeting requirements of the growth of the high electron mobility two-dimensional electron gas material, in other words, having a high electron mobility and a low terahertz loss. That is to say, appropriate two-dimensional electron gas substrate material, which is suitable to be used not only as the two-dimensional electron gas substrate but also as the terahertz resonant cavity, is selected. Hence, both aspects are comprehensively taken into consideration. Sapphire, due to its high resistivity and small absorption of the terahertz radiation, may be used as material of the resonant cavity. Material, for example, quartz crystal and high-resistance monocrystalline silicon, may be selected. The thickness of the material is determined by the target terahertz emission frequency, and generally may be changed from 10 μm to 300 μm. The sapphire, quartz crystal and high-resistance monocrystalline silicon are merely given as an example, and the material of the resonant cavity of the present invention is not limited thereto. Any material, which is used for supporting the substrate of the two-dimensional electron gas material and has a low terahertz absorption and high transmissivity, may be used.

FIG. 14 shows different strong coupling effects due to different thickness of the resonant cavity. The strong coupling effect between the plasmon and the terahertz resonant cavity mode is obvious when the thickness is smaller, and the strong coupling effect is degraded when the thickness increase.

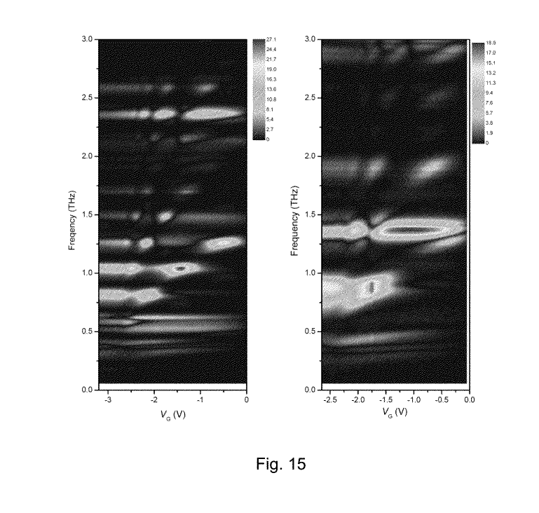

FIG. 15 shows different terahertz emission spectra of the terahertz resonant cavity with different thickness, and different length of the grating, different period of the gate and different spacing of the gate.

The bottom surface of the two-dimensional electron gas substrate material has a mirror-level flatness, and preferably has a metal film having a thickness of over 200 nm (for example, an Au film or a Ti/Au, Ni/Au, Cr/Au or NiCr/Au film) or a total reflector film made of other material as a total reflector to obtain a high reflectivity of the terahertz waves, or to achieve an objective of total reflection on the back by other methods.

A back total reflector is one of key factors to improve the quality factor of the terahertz resonant cavity. Without the total reflector, the terahertz wave within the resonant cavity may leak from the bottom surface, and meanwhile, the mode of the resonant cavity will not agree with the aforementioned mode any more:

instead,

$${f}_{0} = \frac{2 k - 1}{n} \frac{c}{4 D} , k = 1 , 2 , 3 , …$$

the mode of the resonant cavity is:

The total

$${f}_{0} = \frac{k}{n} \frac{c}{4 D} , k = 1 , 2 , 3 , …$$

reflector film on the bottom surface enable the terahertz electric field intensity at the bottom surface within the resonant cavity to be zero. In contrast, in a case where there is no metal total reflector film, the electric field at the bottom surface within the resonant cavity tends to be the maximum. This results in leakage of the terahertz electric field.

The distance between the two-dimensional electron gas and a surface of the two-dimensional electron gas mesa is preferably within a range from 20 nm to 50 nm, and the present invention is not limited thereto. Allowed by the growth process of the high-electron-mobility two-dimensional electron gas material, the smaller the distance between the two-dimensional electron gas and the surface of the two-dimensional electron gas mesa is, the better the enhancing effect of the coupling between the terahertz wave mode and the plasma wave mode by the grating is.

In the present invention, the concentration of the electron gas may be tuned by the gate voltage and the emission frequency of the terahertz waves may be controlled by adjusting the length of the gate of the grating. Furthermore, the emission frequency of the terahertz radiation may be controlled by adjusting the cavity length of the terahertz resonant cavity.

A grating-resonant cavity structure as shown in FIG. 1, FIG. 3A and FIG. 3B is the core structure of the terahertz source in the present invention. The electric field of the mode of the terahertz resonant cavity is strong at the two-dimensional electron gas coupled by the grating. A grating coupler effectively couples the cavity mode of the terahertz resonant cavity with the plasma wave mode within the two-dimensional electron gas to generate the enhanced terahertz electric field at edges of the gate of the grating. The plasma wave is excited in the regulation gated region, i.e., a two-dimensional electron gas region below the gate. Due to the strong coupling between the plasma wave and the mode of the terahertz resonant cavity, the plasmon polariton is formed in a two-dimensional electron gas system under the grating-resonant cavity coupling, thus to realize the high-efficiency conversion from the plasma wave to the terahertz wave. The conversion from the applied electric energy to the plasma wave energy can be realized by an excitation method using the source-drain current, or using the tunneling current from the gate to the two-dimensional electron gas.

In the present invention, the plasma wave may be excited by weak energy injection, that is, zero excitation energy. The generation of the terahertz emission by electrical excitation of the plasmon polariton avoids the excitation of a single electron, and improves the conversion efficiency from the injected energy to the terahertz wave.

Since the plasma wave mode and the terahertz wave mode are in a strong coupling state, the terahertz source chip in this implementation has at least the following advantages:

(1) the life of the plasmon polariton may be prolonged by improving the quality factor of the terahertz resonant cavity; (2) the conversion efficiency from the plasma wave to the terahertz wave emission is high; (3) the conversion efficiency from the injected current to the plasma wave is high; (4) the terahertz emission frequency may be effectively determined by the terahertz resonant cavity; and (5) the terahertz wave emission frequency may be effectively determined by the concentration of the two-dimensional electron gas.

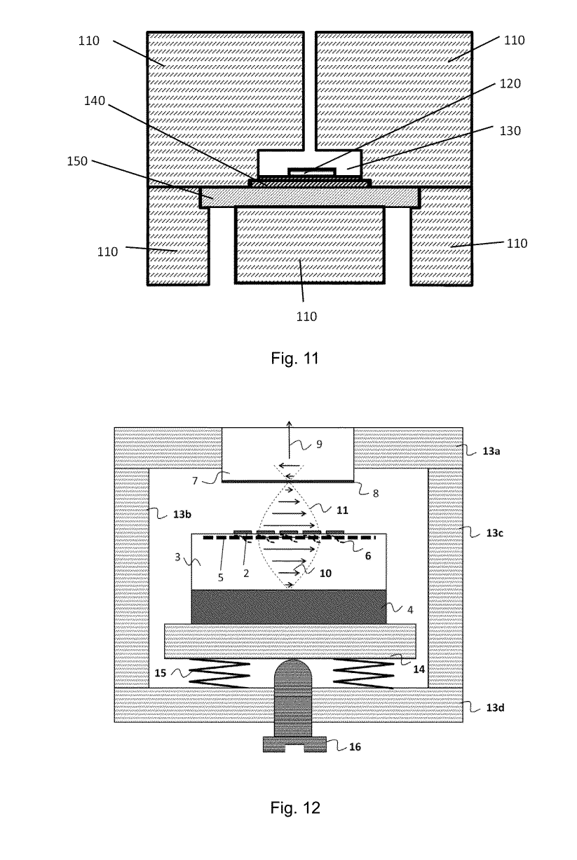

The first terahertz source chip as described above may be encapsulated on a chip holder and/or a printed circuit board (PCB) by a wire bonding process, thus to form a terahertz source device. In order to further collect the terahertz waves emitted from the resonant cavity effectively, the encapsulated source device may be integrated into a high-conductivity oxygen-free copper waveguide to form a terahertz source assembly, as shown in FIG. 11. In FIG. 11, the reference numeral 110 denotes an oxygen-free copper frame, the source chip 120 is encapsulated in the chip holder 140 and further integrated with the PCB 150, and the formed source device is finally integrated into a hollow cavity 130 in the waveguide.

The methods for manufacturing the terahertz source chip, the source device and the source assembly described above will be described below.

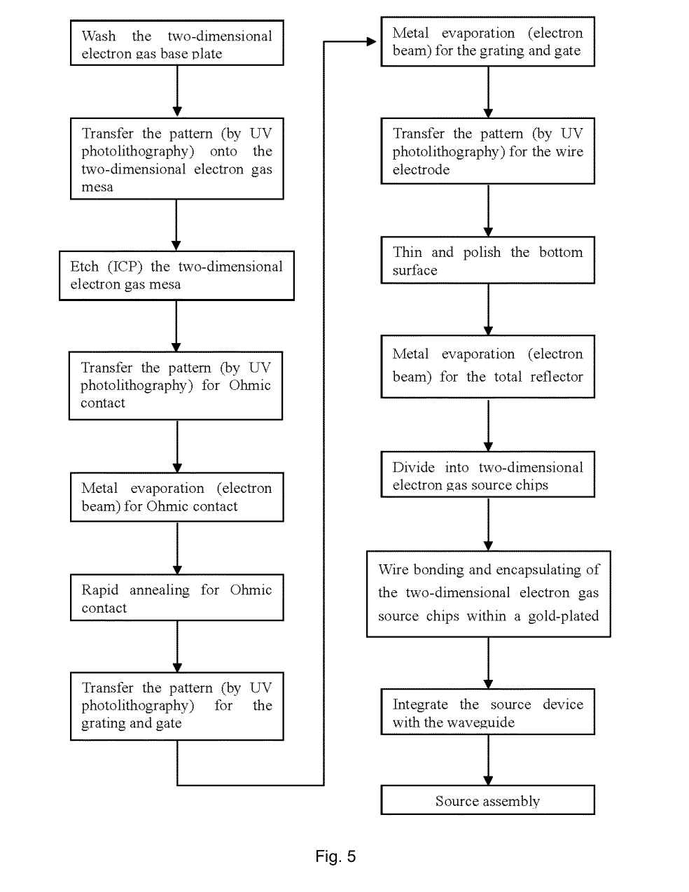

FIG. 4 shows a general process of manufacturing the terahertz source chip (the first terahertz source chip) of this implementation 1, and FIG. 5 shows an example of technological processes of manufacturing the terahertz source assembly of this implementation 1. As shown in FIG. 4, and referring to FIG. 5, the method specifically includes the following steps.

S410: A two-dimensional electron gas mesa is formed.

First, a two-dimensional electron gas wafer having substrate material is washed. The two-dimensional electron gas wafer has the substrate material on the back and the two-dimensional electron gas material in the front, and the two-dimensional electron gas material may be grown on the substrate material by metal organic chemical vapor deposition (MOCVD) or molecular beam epitaxy (MBE) or the like, and has an atomic-level flatness.

Then, the pattern of the two-dimensional electron gas mesa is transferred onto the wafer by ultraviolet (UV) lithography. The two-dimensional electron gas material is etched by using an inductively coupled plasma etching, or reactive-ion etching, or ion beam etching process, or a wet chemical etching process to form a two-dimensional electron gas mesa structure.

S420: An electrode and a metal coupling grating used for exciting a plasma wave in the two-dimensional electron gas are formed on the two-dimensional electron gas mesa.

The electrode used for exciting the plasma wave may be a source and a drain both formed on the two-dimensional electron gas mesa 1 and become Ohmic contacts with the two-dimensional electron gas mesa 1; and also may be at least one of the source and the drain and a gate, where the gate may be the metal coupling grating or a separate gate separated from the metal coupling grating. An exemplary process, in a case when the metal coupling grating is used as the gate, will be described below. The metal coupling grating and the gate, separated from each other, may be formed on the two-dimensional electron gas mesa using a process similar to that of forming the gate of the grating, in a case where the gate is formed separately.

First, a source and a drain both forming Ohmic contact with the two-dimensional electron gas mesa may be formed on the two-dimensional electron gas mesa. The source and the drain may be implemented by a conventional Ohmic contact process, and the contact resistance is as small as possible without special requirements. For example, specifically, an Ohmic contact pattern may be formed on the two-dimensional electron gas mesa by ultraviolet lithography. A multi-layer metal structure used for forming the Ohmic contacts is evaporated by the electron beam evaporation or thermal evaporation or magnetron sputtering process or the like, and an Ohmic contact metal pattern is formed after the metal is lift off. For AlGaN/GaN two-dimensional electron gas material, the multi-layer metal structure may be made of, for example, Ti/Al/Ni/Au. For AlGaAs/GaAs two-dimensional electron gas material, the multi-layer metal structure may be made of, for example, AuGe/Ni/AuGe. Here, the material of the multi-layer metal structure is merely given as an example. Then, the Ohmic contact is formed by rapid annealing. Au, Ti/Au, Ni/Au, Cr/Au or NiCr/Au may be evaporated by the electron beam evaporation or thermal evaporation or magnetron sputtering process, and the metal electrodes (source and drain) structure are formed after the metal is lift off, wherein Au is the main material of the grating and the gate and has a thickness of over 50 nm, and Ti, Ni, Cr and NiCr layers are the adhesion layers between the Au layer and the two-dimensional electron gas mesa or the underlayer on which the electrode is located and generally have a thickness of below 50 nm

Next, a metal coupling grating serving as the gate is formed on the two-dimensional electron gas mesa. For example, specifically, a grating pattern may be formed on the two-dimensional electron gas mesa by the ultraviolet lithography process or the electron beam lithography process or a laser interference exposure process or similar processes. Metal (generally gold or alloy containing gold, for example, Ti/Au, Ni/Au, Cr/Au or NiCr/Au or the like) having a high electric conductivity is evaporated by the electron beam evaporation or thermal evaporation or magnetron sputtering process to form the metal grating structure.

A corresponding wire bonding electrode is formed after the grating and the gate are formed. For example, the transfer of patterns of the wire bonding electrodes of the terahertz grating gate and the source and drain may be achieved by ultraviolet lithography. That is, the patterns are transferred onto the two-dimensional electron gas mesa. Next, Au, Ti/Au, Ni/Au, Cr/Au or NiCr/Au or the like is evaporated by the electron beam evaporation or thermal evaporation or magnetron sputtering process, and the gate and the wire bonding electrodes are formed after the metal is lift off.

S430: The two-dimensional electron gas substrate is thinned and polished to form a terahertz resonant cavity.

The two-dimensional electron gas substrate is thinned and polished so that the two-dimensional electron gas substrate has a thickness required by the design and the back thereof has a mirror-level flatness. Preferably, a layer of gold film or film of other metals (including alloy) may be evaporated onto the bottom surface of the two-dimensional electron gas substrate to obtain a high reflectivity of the terahertz waves, serving as the back total reflector. For example, a metal film (for example, Au, Ti/Au, Ni/Au, Cr/Au or NiCr/Au) may be evaporated on the back of the two-dimensional electron gas substrate by the electron beam evaporation or thermal evaporation or magnetron sputtering process or the like to form a terahertz total reflector. The higher the reflectivity of the total reflector is, the better the total reflection effect is.

The terahertz source chip having a high conversion efficiency is formed as above.

Alternatively, in the step of forming the two-dimensional electron gas mesa, the two-dimensional electron gas material may be transferred onto the surface of the terahertz resonant cavity and then the two-dimensional electron gas mesa is formed on the surface of the resonant cavity.

If several terahertz source chips are formed on a big two-dimensional electron gas substrate, the method further includes dividing the several terahertz source chips into individual terahertz source chips. For example, the several terahertz source chips may be divided into individual terahertz source chips by a laser dissociation process or a laser cutting process or a manual dissociation process.

Further, the individual terahertz source chips may be encapsulated onto the chip holder and/or a PCB by wire bonding, thus to be encapsulated as a terahertz source device. Further, in order to collect the terahertz waves emitted from the resonant cavity more effectively, the encapsulated source device may be integrated into a high-conductivity oxygen-free copper waveguide to form a terahertz source assembly, as shown in FIG. 11.

The specific technological processes in the aforementioned steps are merely given as an example, and the present invention is not limited thereto. As each of the steps may include several processes, it is possible to perform the processes in different steps alternately, instead of performing in this order as described above. For those skilled in the art, various variations and changes may be made in the processes and orders for forming the elements, according to the description of the application under the premise of manufacturing the structures sought to be protected by the application, and those variations and changes should fall into the protection scope of the present invention.

Implementation 2

Further improvements are made in this implementation based on Implementation 1. In this implementation, another chip (also called a second terahertz source chip in this implementation), a corresponding source device and assembly, and manufacturing methods thereof are provided, to reduce the loss of the terahertz waves and thus to further improve the quality factor of the terahertz resonant cavity. As a result, the coupling strength between the cavity mode of the resonant cavity and the plasma wave mode is enhanced and the conversion efficiency is improved.

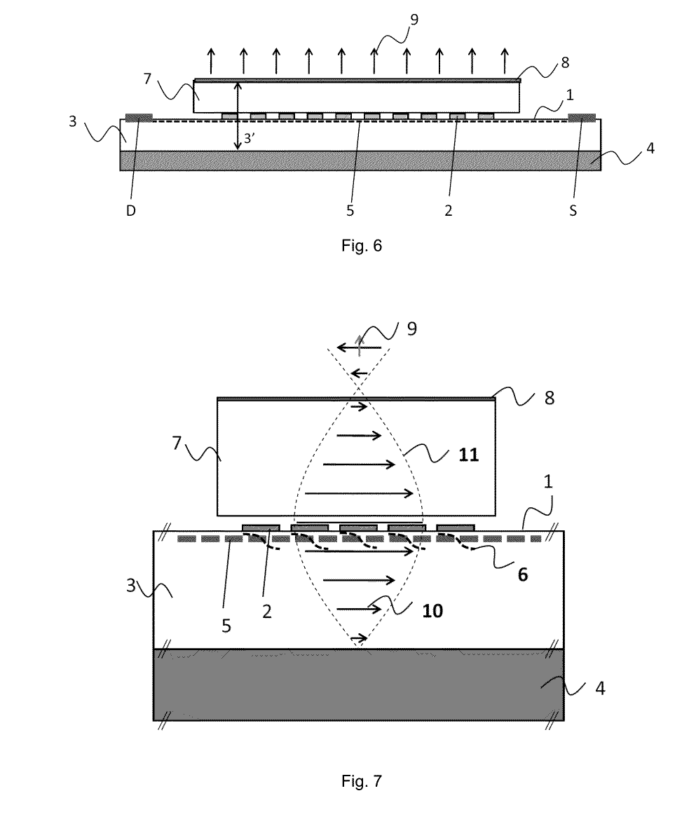

FIG. 6 is a schematic structure diagram of the terahertz source chip according to this implementation. FIG. 7 shows a form of the plasma wave mode and the cavity mode of the terahertz resonant cavity under the grating-resonant cavity coupling.

As shown in FIG. 6, the terahertz source chip in this implementation includes: a two-dimensional electron gas mesa 1; an electrode (for example, a source S and a drain D, a source and a gate; a drain and a gate; or a source, a drain and a gate) formed on the two-dimensional electron gas mesa 1 for exciting a plasma wave; a terahertz resonance cavity 3 formed below the two-dimensional electron gas mesa 1 for serving as a two-dimensional electron gas substrate; and a metal coupling grating 2 formed above the two-dimensional electron gas mesa for coupling a cavity mode of the terahertz resonant cavity with the two-dimensional electron gas and a plasma wave mode thereof. These structures are the same as that of the source chip in Implementation 1, and will not be repeatedly described in this implementation. Additionally, the terahertz source chip in Implementation 2 further includes: a medium resonant cavity slab 7 formed above the metal coupling grating; and a half reflector or a high reflector 8 formed above the medium resonant cavity slab for serving as an emitting surface of the terahertz radiation 9. That is to say, the second terahertz source chip in this implementation includes, in addition to the structures of the first terahertz source chip in Implementation 1, the medium resonant cavity slab 7 and a partial reflector (for example, a high reflector) 8.

In this implementation, the material of the dielectric resonant cavity slab is the same as or similar to the substrate material of the two-dimensional electron gas chip (both have an equivalent dielectric constant or refractive index to the terahertz light), and has a same or approximate thickness. An upper surface and a lower surface of the dielectric resonant cavity slab have a mirror-level flatness. The upper surface may be coated with a semi-transmissive or high-reflecting metal film which is the emitting surface of the terahertz radiation. The first terahertz source chip and the dielectric resonant cavity slab may be precisely integrated together by a flip-chip bonding process, with their surfaces being parallel to each other, to form a terahertz Fabry-Perot resonant cavity 3′ having a high quality factor. As shown in FIG. 7, a limited number of terahertz resonant modes, i.e., standing wave modes, may be formed in the Fabry resonant cavity. The standing wave mode forms an anti-node at the location of two-dimensional electron gas, for example, such as the terahertz electric field intensity envelope 11 indicated in FIG. 7. Then, the near field is strengthened by the metal grating 2 above the two-dimensional electron gas, to realize resonance between the terahertz wave resonance mode and the plasma wave 6 in the two-dimensional electron gas, in order to form plasmon polariton, thus to generate the terahertz radiation 9.

As another implementation, the positions of the dielectric resonant cavity slab 7 and the high reflector 8 in FIG. 6 may be exchanged. However, at this time, the spacing between the grating and the high reflector should be adjusted correspondingly, so that the distance between the high reflector and the total reflector on the bottom surface meets a standing wave condition and the standing wave forms an anti-node at the location of the two-dimensional electron gas.

The dielectric resonant cavity slab 7 and the high reflector 8 may be of a spherical structure or an aspheric structure. Additionally, the high reflector 8 and the total reflector 4 further may be replaced by aspheric reflectors on the basis of structures of FIG. 6, to constitute a terahertz resonant cavity having a better stability. The high reflector 8 and the total reflector may also be asymmetric reflectors to constitute an unsteady terahertz resonant cavity which may be used for a high-power terahertz source.

As shown in FIG. 7, the electric field 10 of the mode of the terahertz resonant cavity is the strongest at the location of two-dimensional electron gas. A grating coupler effectively couples the cavity mode of the terahertz resonant cavity with the two-dimensional electron gas to generate the strengthened terahertz electric field at edges of the gate of the grating. The plasma wave is excited in the gated regions, i.e., a two-dimensional electron gas region below the gate of the grating. Due to the strong coupling between the plasma wave and the terahertz resonant cavity mode, the plasmon polariton is formed in the two-dimensional electron gas system under grating-resonant cavity coupling.

A source-drain current or a gate-channel current drives the excitation of the plasmon polariton, and the terahertz wave is emitted outside the resonant cavity through the high reflector on the upper surface of the resonant cavity slab.

The second terahertz source chip as described above may be encapsulated on a chip holder and/or a printed circuit board (PCB) by wire bonding, thus to form a terahertz source device. In order to further collect the terahertz waves emitted from the resonant cavity effectively, the encapsulated source device may be integrated into a high-conductivity oxygen-free copper waveguide to form a terahertz source assembly, as shown in FIG. 11.

The second terahertz source chip according to this implementation has advantages of the first source chip in Implementation 1. Furthermore, compared with Implementation 1, as the quality factor of the terahertz resonant cavity is significantly improved, the coupling strength between the cavity mode of the terahertz resonant cavity and the plasma wave mode is further improved and the conversion efficiency is improved effectively; and meanwhile, the line width of the emission is reduced and the monochromaticity and coherent property of the terahertz light are strengthened.

Alternatively, the total reflector 4 in the terahertz source chips in FIG. 6 and FIG. 7 may be replaced by a partial reflector (such as a half reflector or a high reflector), and the partial reflector 8 may be replaced by a total reflector. At this time, the terahertz radiation will be emitted from the bottom of the resonant cavity 3 instead of the top of the resonant cavity slab 7.

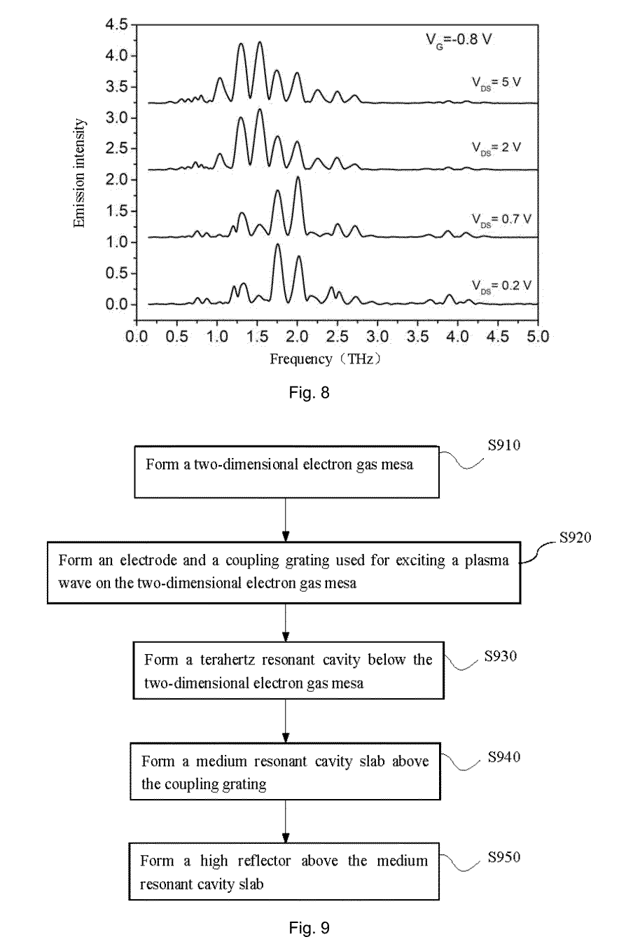

FIG. 8 shows a reflection spectra as a function of gate voltages and source-drain voltages. It can be seen from FIG. 8 that, under a same negative gate voltage (−0.8 V), the higher the voltage between the source and the drain is, the higher the reflection frequency of the reflection spectrum is.

In this implementation, the Fabry-Perot resonant cavity is just given an example, and a non-planar resonant cavity may also be employed, for example, a confocal terahertz resonant cavity.

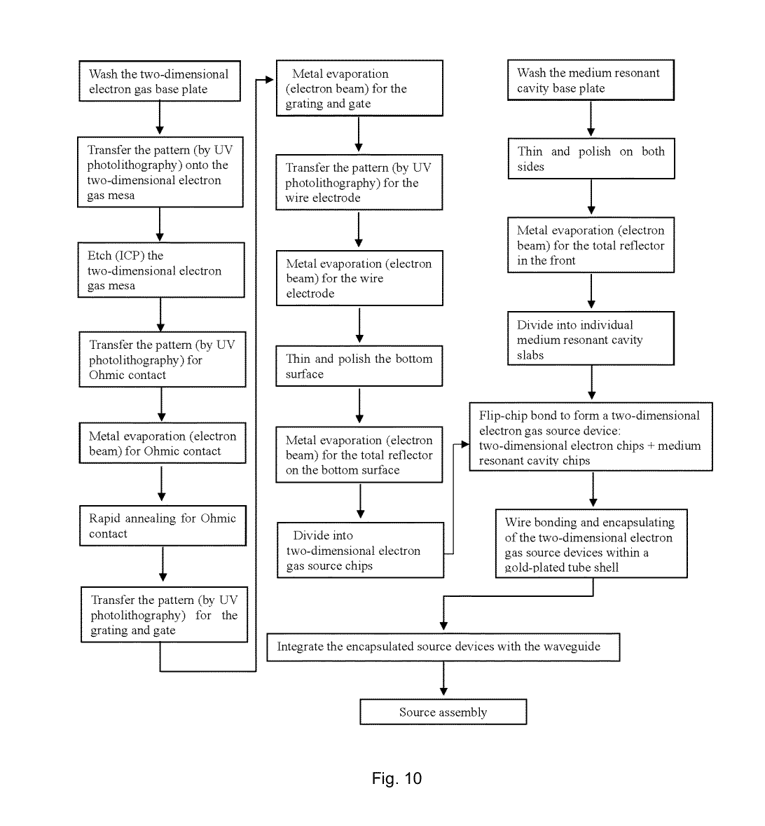

The methods for manufacturing the terahertz source chip, the source device and the source assembly according to this implementation will be described below. FIG. 9 is a brief flowchart of manufacturing the second terahertz source chip according to Implementation 2, and FIG. 10 shows an example of technological processes of manufacturing the terahertz source assembly according to Implementation 2. As shown in FIG. 9, and referring to FIG. 10, the method specifically includes the following steps.

S910 to S930: A first terahertz source chip is manufactured. S910 to S930 are the same as S410 to S430, and will not be repeatedly described here.

S940: A resonant cavity slab is formed on the first source chip.

This step may specifically include: washing the resonant cavity slab material which may be, for example, but not limited to, a sapphire sheet, a high-resistance silicon sheet or a quartz sheet. The resonant cavity slab material may be thinned and polished by the chemical mechanical polishing process to obtain a predetermined thickness of the resonant cavity and a mirror-level flatness.

S940: A partial reflector is formed on the upper surface or the lower surface of the resonant cavity slab. For example, the reflector may be a half reflector or a high reflector.

For example, a Ti/Au, Ni/Au, Cr/Au or NiCr/Au film may be evaporated on the front surface of the resonant cavity slab material by the electron beam evaporation or thermal evaporation or magnetron sputtering process, and a partial reflector mirror is formed by controlling the thickness of the film. Alternatively, a partial reflector mirror may be formed on the back surface of the resonant cavity slab. However, at this time, the spacing between the grating and the high reflector should be adjusted correspondingly, so that the distance between the high reflector and the total reflector on the bottom surface meets a standing wave condition and the standing wave forms an anti-node where the two-dimensional electron gas locate.

In this implementation, the first terahertz source chip and the resonant cavity slab may be aligned and integrated as the integral second terahertz source chip in this implementation by the flip-chip bonding process or the gold-gold bonding process. In order to realize the integration of the first source chip with the dielectric resonant cavity slab, after the resonant cavity slab and the reflector are made, the following operations are further performed:

the transfer of a pattern of a wafer bonding region on the back of the resonant cavity slab material is realized by ultraviolet lithography, that is, the pattern of the wafer bonding region is transferred onto the back of the resonant cavity slab material.

Next, Ti/Au or Ni/Au or Cr/Au or NiCr/Au is evaporated on the back of the resonant cavity slab material by the electron beam evaporation or thermal evaporation or magnetron sputtering process to form a metal region for wafer bonding.

If a large resonant cavity slab is made, the resonant cavity slab material may be divided into individual resonant cavity slabs by the laser dissociation process or the laser cutting process or the manual dissociation process before integrating the two-dimensional electron gas chip with the resonant cavity slab.

In the aforementioned methods, the total reflector 4 may be replaced by a partial reflector (for example, a half reflector or a high reflector), and the partial reflector 8 may be replaced by a total reflector. At this time, the generated terahertz radiation will be emitted from the bottom of the resonant cavity 3, instead of the top of the resonant cavity slab 7.

In addition to fixedly integrating the resonant cavity slab with the first terahertz source chip (that is, the cavity length of the terahertz resonant cavity is constant), the terahertz source chip in this implementation may also be arranged, so that the distance between the resonant cavity slab and the first terahertz source chip is fine tuned, to adjust the cavity length of the terahertz resonant cavity 3′, thus to flexibly control the emission frequency of the terahertz waves. FIG. 12 is a sectional view of a terahertz source device having a resonant cavity length adjusting apparatus according to one implementation. This resonant cavity length adjusting apparatus adjusts the distance between the resonant cavity 3 and the resonant cavity slab 7 by using springs and a thread pair, thus to adjust the cavity length of the terahertz resonant cavity 3′. In FIG. 12, the resonant cavity length adjusting apparatus adjusts the cavity length by moving the first terahertz source chip. The resonant cavity length adjusting apparatus includes: a frame including a bottom plate 13a, side walls 13b and 13c and a top plate 13d; a chip holder 14 arranged below the first terahertz source chip structure and fixed with the first terahertz source chip (or fixed with the resonant cavity 3); two springs 15 arranged between the chip holder 14 and the bottom plate 13a of the frame, with two ends of the spring 15 being respectively fixed onto the holder 14 and the bottom plate 13a; and a distance adjusting component (for example, a thread pair) 16 provided on the bottom plate 13a. The resonant cavity slab 7 is embedded into an opening in the middle of the top plate. The thread pair 16 arranged on the bottom plate 13a is capable of passing through the bottom plate 13a and acting on the chip holder 14 (pressed against the chip holder) by means of an acting force (for example, tensile force) of the springs 15 between the chip holder 14 and the bottom plate 13a, and is capable of adjusting the distance between the bottom plate 13a and the chip holder 14, i.e., the distance between the resonant cavity and the resonant cavity slab, by rotating the thread pair to move up and down, thus to adjust the cavity length of the resonant cavity.

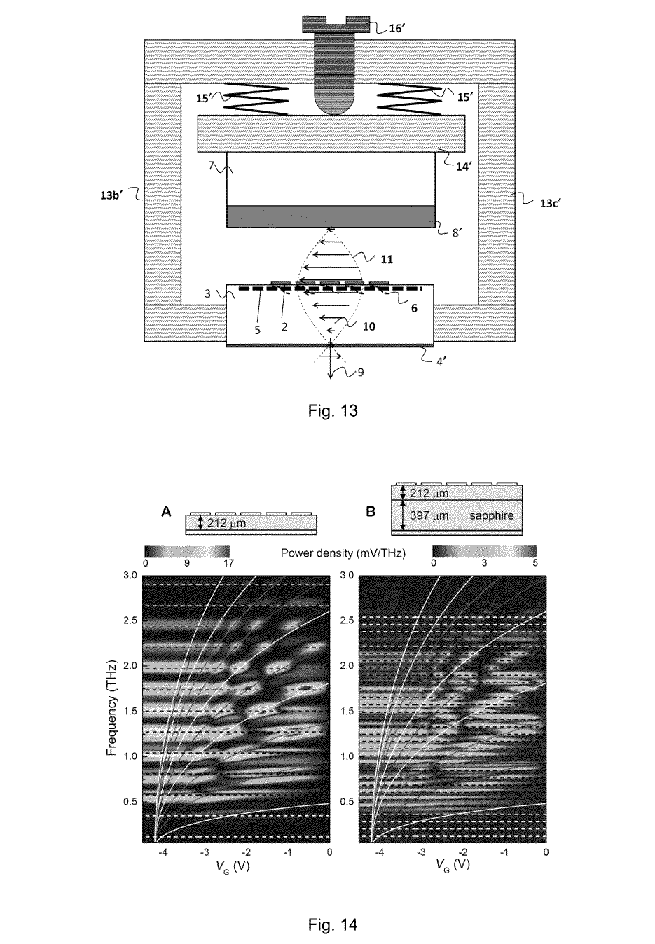

FIG. 13 is a sectional view of a terahertz source device having a resonant cavity length adjusting apparatus according to another implementation. In this implementation, the resonant cavity length adjusting apparatus adjusts the cavity length by moving the resonant cavity slab. The resonant cavity length adjusting apparatus includes: a frame including a top plate 13a′, side walls 13b′ and 13c′ and a bottom plate 13d′ a resonant cavity slab holder 14′ arranged above the resonant cavity slab 7 and fixed with the resonant cavity slab 7; two springs 15′ arranged between the resonant cavity slab holder 14′ and the top plate 13a′ of the frame, with two ends of the spring 15′ being respectively fixed onto the holder 14′ and the top plate 13a′; and a distance adjusting component (for example, a thread pair) 16′ provided on the top plate 13a′. The resonant cavity 3 is embedded into the opening in the middle of the bottom plate 13d′. The thread pair 16′ arranged on the top plate 13a′ is capable of passing through the top plate 13a′ and acting on the resonant cavity slab holder 14′ (pressed against the resonant cavity slab holder 14′) by means of an acting force of the springs 15′ between the resonant cavity slab holder 14′ and the top plate 13a′, and is capable of adjusting the distance between the top plate 13a′ and the resonant cavity slab holder 14′, i.e., the distance between the resonant cavity 3 and the resonant cavity slab 7, by rotating the thread pair 16′ to move up and down, thus to adjust the cavity length of the resonant cavity. In this implementation, as the resonant cavity slab holder 14′ is arranged above the resonant cavity slab 7, the emission of the terahertz radiation 9 is influenced. Hence, the terahertz source device in this implementation may be arranged to emit the terahertz radiation 9 from the bottom of the resonant cavity. At this time, the total reflector on the bottom surface of the resonant cavity 3 is replaced by a half reflector or a high reflector, and the half reflector on the upper surface or the lower surface of the resonant cavity slab 7 is replaced by a total reflector.

Adjusting the cavity length of the resonant cavity by the springs and the thread pair are merely given as an example, other replacements or variations are readily appreciated according to the description of the present invention for those skilled in the art.

The second terahertz source chip as described above may be encapsulated on a chip holder or a PCB by wire bonding, thus to form a terahertz source device. In order to further collect the terahertz radiation emitted from the resonant cavity effectively, the encapsulated source device may be integrated into a high-conductivity oxygen-free copper waveguide to form a terahertz source assembly, as shown in FIG. 11.

1-52. (canceled)

53. A terahertz source chip, comprising:
an electron gas mesa;
an electrode formed on the electron gas mesa;
a terahertz resonant cavity formed below the electron gas mesa, the terahertz resonant cavity having a total reflector or a partial reflector on a bottom surface thereof; and
a grating formed on the electron gas mesa,
wherein
the terahertz source chip further comprises: a resonant cavity slab provided above the grating,
or, the electrode comprises: a source and a drain both become Ohmic contacts with the electron gas mesa, and a gate, wherein the grating is formed as the gate, or the gate is formed separately,
or, the thickness of the terahertz resonant cavity is less than 1000 μm.

54. The terahertz source chip according to claim 53, characterized in that,
a total reflector is arranged on a bottom surface of the terahertz resonant cavity, and a partial reflector is formed on an upper surface or a lower surface of the terahertz resonant cavity slab; or
a partial reflector is arranged on a bottom surface of the terahertz resonant cavity, and a total reflector is formed on an upper surface or a lower surface of the terahertz resonant cavity slab.

55. The terahertz source chip according to claim 54, characterized in that the distance between the partial reflector and the total reflector meets a standing wave condition and enables the standing wave to form an anti-node where the electron gas locates.

56. The terahertz source chip according to claim 53, characterized in that there is a potential difference between the gate and the electron gas, and the potential of the gate is lower than that of the electron gas to generate a tunneling current between the gate and the electron gas thus to excite a plasma wave in the electron gas.

57. The terahertz source chip according to claim 53, characterized in that, the electron gas mesa is made of electron gas material, wherein, the electron gas material is one or more of the following: GaN/AlGaN, InAlN/GaN, GaAs/AlGaAs, InGaAs/AlGaAs, Si/SiGe, InN, Si/SiO₂, graphene and MoS₂, diamond, single-layer, double-layer and triple-layer graphene, Si/SiO₂/Al metal-oxide-semiconductor, silicon nanowire, GaAs nanowire, InGaAs nanowire GaN nanowire, carbon nanotube, zinc oxide nanowire, doped silicon bulk material, doped GaAs bulk material, doped GaN bulk material, doped germanium bulk material, doped InGaAs bulk material, doped InP bulk material, doped SiC bulk material, doped diamond bulk material and doped zinc oxide bulk material.

58. The terahertz source chip according to claim 54, further comprising an adjusting apparatus used for adjusting the distance between the resonant cavity and the resonant cavity slab.

59. The terahertz source chip according to claim 58, characterized in that the adjusting apparatus comprises:
a frame comprising a bottom plate, a side wall and a top plate;
a pedestal provided below the resonant cavity and fixed with the resonant cavity;
at least one spring provided between the pedestal and the bottom plate of the frame, two ends of the spring being respectively fixed on the pedestal and the bottom plate; and
a distance adjusting component provided on the bottom plate;
wherein the resonant cavity slab is embedded into an opening in the middle of the top plate, the distance adjusting component arranged on the bottom plate is capable of passing through the bottom plate to act on the pedestal by means of a tensile force of the spring between the pedestal and the bottom plate, thus to adjust the distance between the resonant cavity and the resonant cavity slab by moving the distance adjusting component up and down.

60. A terahertz source chip, comprising:
an electron gas mesa; an electrode formed on the electron gas mesa;
a terahertz resonant cavity formed below the electron gas mesa, the terahertz resonant cavity having a total reflector or a partial reflector on a bottom surface thereof;
a grating formed on the electron gas mesa;
a resonant cavity slab provided above the grating; and
a total reflector provided on an upper surface or a lower surface of the resonant cavity slab.

61. The terahertz source chip according to claim 60, further comprising an adjusting apparatus used for adjusting the distance between the resonant cavity and the resonant cavity slab.

62. A terahertz source device, comprising the terahertz source chip according to claim 53, the terahertz source chip being encapsulated on a chip holder or a printed circuit board.

63. A terahertz source assembly, comprising the terahertz source device according to claim 62, the terahertz source device being integrated into a waveguide.

64. A method for manufacturing a terahertz source chip, comprising steps of:
forming an electron gas mesa on an electron gas substrate;
forming an electrode and a grating for exciting a plasma wave on the electron gas mesa; and
forming a terahertz resonant cavity based on the electron gas substrate,
wherein the formation of the terahertz resonant cavity comprises steps of:
thinning and polishing the electron gas substrate from the back of the substrate to obtain a predetermined thickness of the resonant cavity and a predetermined flatness of mirror surfaces; and
forming a total reflector or a partial reflector on the back of the thinned and polished electron gas substrate.

65. The method according to claim 64, further comprising a step of:
integrating a resonant cavity slab above the grating in parallel, wherein a total reflector is arranged on a bottom surface of the terahertz resonant cavity, and a partial reflector is formed on an upper surface or a lower surface of the resonant cavity slab; or, a partial reflector is arranged on a bottom surface of the terahertz resonant cavity, and a total reflector is formed on an upper surface or a lower surface of the resonant cavity slab.

66. The method according to claim 65, characterized in that a distance between the partial reflector and the total reflector meets a standing wave condition and enables the standing wave to form an anti-node where the electron gas locates.

67. A method for forming a terahertz source chip, comprising steps of:
transferring electron gas material onto an upper surface of the terahertz resonant cavity, wherein the terahertz resonant cavity has a total reflector or a partial reflector on the lower surface thereof;
forming an electron gas mesa on the upper surface of the terahertz resonant cavity; and
forming an electrode and a grating for exciting a plasma wave on the electron gas mesa, and
integrating a resonant cavity slab above the grating, wherein the total reflector is arranged on a bottom surface of the terahertz resonant cavity, and the partial reflector is formed on an upper surface or a lower surface of the resonant cavity slab; or, the partial reflector is arranged on the bottom surface of the terahertz resonant cavity, and the total reflector is formed on the upper surface or the lower surface of the resonant cavity slab.

68. The method according to claim 67, characterized in that a distance between the partial reflector and the total reflector meets a standing wave condition and enables the standing wave to form an anti-node where the electron gas locates.

69. A method for manufacturing a terahertz source chip, comprising steps of:
forming a two-dimensional electron gas mesa on a two-dimensional electron gas substrate;
forming an electrode and a metal coupling grating for exciting a plasma wave on the two-dimensional electron gas mesa; and
forming a terahertz resonant cavity based on the two-dimensional electron gas substrate, wherein the formation of the terahertz resonant cavity comprises steps of:
thinning and polishing the two-dimensional electron gas substrate from the back of the substrate to obtain a predetermined thickness of the resonant cavity and a predetermined flatness of mirror surfaces;
forming a partial reflector on the back of the thinned and polished two-dimensional electron gas substrate; and
integrating a resonant cavity slab above the metal coupling grating, wherein a total reflector is formed on an upper surface or a lower surface of the resonant cavity slab.

70. A method for exciting a plasmon, characterized in that tunneling electrons are injected by a potential difference applied between an electrode and an electron gas channel, wherein, the electrode is a gate.

71. A device for exciting a plasmon, comprising:
an electrode;
an electron gas channel; and
a barrier layer between the electrode and the electron gas channel;
wherein there is a potential difference between the electrode and the electron gas channel, and the potential of the electrode is lower than that of the electron gas channel.

72. The device for exciting a plasmon according to claim 71, characterized in that the electrode is a gate.

73. The device for exciting a plasmon according to claim 71, characterized in that the barrier layer is semiconductor material, a vacuum layer or quantum well material.

74. A terahertz strong coupling component, comprising a grating and a terahertz resonant cavity, the grating being located above the terahertz resonant cavity, wherein, the thickness of the terahertz resonant cavity is less than 1000 μm.

75. The terahertz strong coupling component according to claim 74, characterized in that the distance between the electron gas channel and the grating should be adjusted to be 1 nm to 100 nm.

76. The terahertz strong coupling component according to claim 75, further comprising a resonant cavity slab provided above the grating, the resonant cavity slab and the terahertz resonant cavity being respectively on both sides of the grating.

77. The terahertz strong coupling component according to claim 76, characterized in that,
a total reflector is arranged on a bottom surface of the terahertz resonant cavity, and a partial reflector is formed on an upper surface or a lower surface of the terahertz resonant cavity slab; or
a partial reflector is arranged on the bottom surface of the terahertz resonant cavity, and a total reflector is formed on an upper surface or a lower surface of the resonant cavity slab.

78. The terahertz strong coupling component according to claim 77, characterized in that a distance between the partial reflector and the total reflector meets a standing wave condition and enables the standing wave to form an anti-node where the electron gas locates.
